(19) United States
(12) Patent Application Publication
(10) Pub. No.: US 2026/0136643 A1
(43) Pub. Date: May 14, 2026

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chih-Hong HWANG, New Taipei City (TW); Tzung Yi WU, Hsinchu City (TW); Cheng Ying LIN, Hsinchu City (TW); Chieh-Hsin LIN, Hsinchu County (TW); Xiaodong WANG, Hsinchu City (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/944,791

(22) Filed: Nov. 12, 2024

(51) Int. Cl. H01L 21/8234; H01L 23/522; H01L 23/528; H01L 27/088; H01L 29/06; H01L 29/08; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 62/151; H10D 64/017; H10D 84/013; H10D 84/0135; H10D 84/0149; H10D 84/0151; H10D 84/83; H10W 20/42; H10W 20/427

(57) ABSTRACT

A semiconductor structure includes a substrate, a gate pattern structure, source/drain contacts on opposite sides of the gate pattern structure, a first via and a second via extending through the substrate and in contact with the source/drain contacts, respectively, a gate-cut isolation structure cutting the gate pattern structure. The gate-cut isolation structure extends to a position laterally between the first via and the second via.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a semiconductor device in accordance with some embodiments of the present disclosure.

FIGS. 1B, 1C, 1D, and 1E are cross-sectional views along lines C1-C1, C2-C2, C3-C3, and C4-C4 of FIG. 1A, respectively.

FIGS. 2A to 8E illustrate a method in various stages of forming a semiconductor device in accordance with some embodiments of the present disclosure.

FIG. 9A is a top view of a semiconductor device in accordance with some embodiments of the present disclosure.

FIGS. 9B, 9C, 9D, and 9E are cross-sectional views along lines C1-C1, C2-C2, C3-C3, and C4-C4 of FIG. 9A, respectively.

FIGS. 10A to 13E illustrate a method in various stages of forming a semiconductor device in accordance with some embodiments of the present disclosure.

FIG. 14 is a cross-sectional view of a semiconductor device in accordance with some embodiments of the present disclosure.

FIGS. 15 to 20 are block diagrams of semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

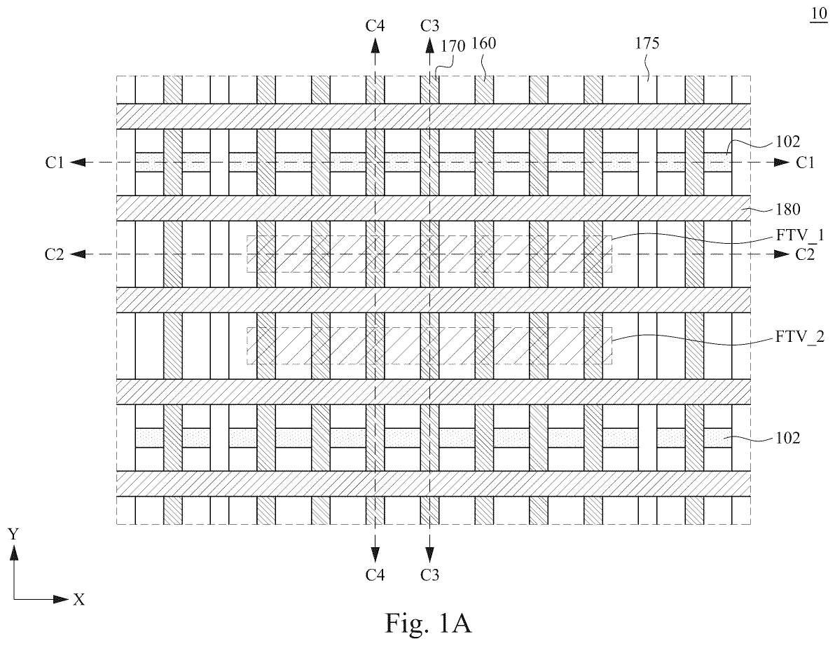

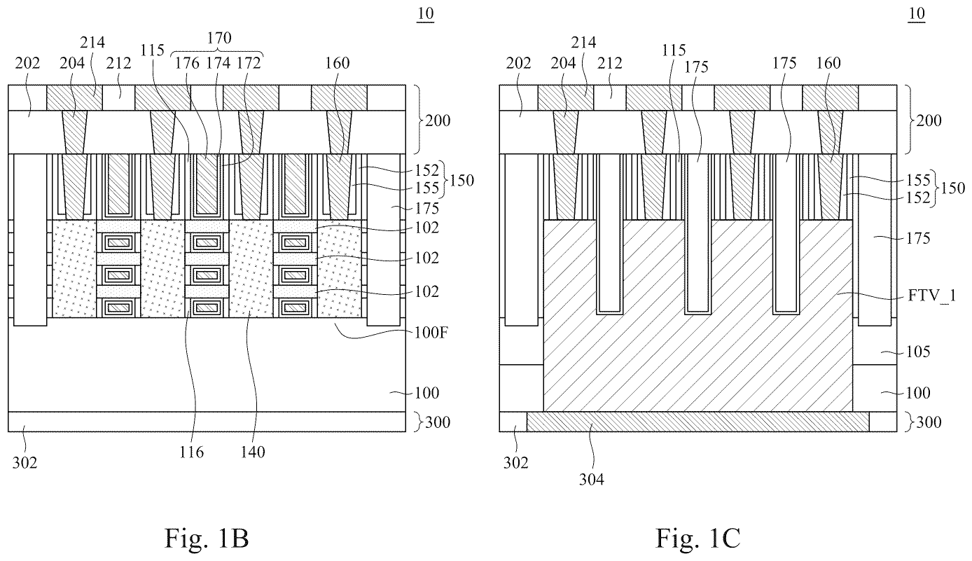

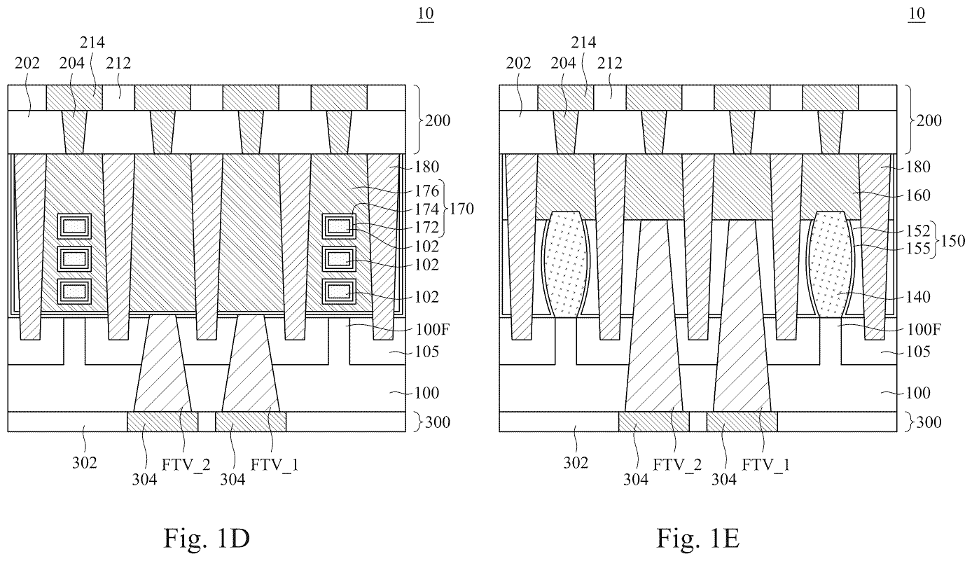

FIG. 1A is a top view of a semiconductor device in accordance with some embodiments of the present disclosure. FIGS. 1B, 1C, 1D, and 1E are cross-sectional views along lines C1-C1, C2-C2, C3-C3, and C4-C4 of FIG. 1A, respectively. It is noted that some elements in the cross-sectional views of FIGS. 1B, 1C, 1D, and 1E are not illustrated in FIG. 1A for brevity. FIGS. 1A to 1E illustrate an example of a feed-through-via (FTV) cell 10, which includes at least one feed-through-via (FTV) extends from the backside of a substrate to the front side of the substrate, which will be discussed in more detail in the following content.

The FTV cell 10 includes a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include crystalline semiconductor material, such as silicon (Si). Other suitable semiconductor material may include germanium (Ge), silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), or combinations thereof. In some embodiments, the substrate 100 is un-doped. The substrate 100 includes a plurality of semiconductor fins 100F protruding upward from the top surface of the substrate 100. In some embodiments, the semiconductor fins 100F may include a same material as the substrate 100, or may include a different material than the substrate 100.

The FTV cell 10 includes an isolation structure 105 over the substrate 100 and laterally surrounding the semiconductor fins 100F. The isolation structure 105 may be shallow trench isolation (STI) structures, suitable isolation structures, combinations of the foregoing, or the like. In some embodiments, the isolation structure 105 may be made of oxide (e.g., silicon oxide), nitride (e.g., silicon nitride), or combinations thereof.

The FTV cell 10 includes a plurality of stacks of semiconductor channel layers 102, in which the semiconductor channel layers 102 of each stack is vertically stacked above one another over a respective one of the semiconductor fin 100F over the substrate 100. Each of the semiconductor channel layers 102 includes a lengthwise direction extending along a first direction (e.g., X-direction). In some embodiments, the semiconductor layers 102 may be made of pure silicon layers that are free of germanium. In other embodiments, the semiconductor layers 102 may also include silicon germanium (SiGe), or other suitable semiconductor material.

The FTV cell 10 includes a plurality of gate structures 170 having a lengthwise direction along a second direction (e.g., Y-direction) that is substantially perpendicular to the first direction (e.g., X-direction). The gate structures 170 may wrap around each of the semiconductor channel layers 102. In some embodiments, each of the gate structures 170 includes a gate dielectric layer 172, a work function metal layer 174 over the gate dielectric layer 172, and a gate filling metal 176 over the work function metal layer 174. In some embodiments, although the device discussed herein includes a GAA configuration, in other embodiments the device can also be planar device, a FinFET device, a nano-sheet device, a nano-wire device, a fork-sheet device, a CFET, etc.

In some embodiments, the gate dielectric layers 172 and 272 each may include an interfacial layer and a high-k dielectric layer over the interfacial layer. Examples of interfacial layer may include oxide, such as aluminum oxide (Al₂O₃), silicon oxide (SiO₂), or the like. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layers 176 and 276 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The gate filling metals 176 and 276 may include tungsten (W), aluminum (Al), copper (Cu), or another suitable conductive material(s).

The FTV cell 10 includes gate spacers 115 on opposite sidewalls of each of the gate structures 170. In some embodiments, the gate spacers 115 may be formed of silicon oxide, silicon nitride, silicon oxynitride, combinations thereof. The FTV cell 10 further includes inner spacers 116 vertically between adjacent two of the semiconductor layers 102 and on opposite sides of each of the gate structures 170. In some embodiments, the inner spacers 116 may include a material such as SiN, SiOCN, SiCN, SIOC, although any suitable material, such as low-dielectric constant (low-k) materials having a k-value less than about 3.5, may be utilized.

The FTV cell 10 includes source/drain epitaxy structures 140 on opposite sides of the gate structures 170 and in contact with on opposite ends of each of the semiconductor layers 102. In some embodiments, each of the source/drain epitaxy structures 140 is in contact with as corresponding one of the semiconductor fin 100F. In some embodiments, the source/drain epitaxial structures 140 may be N-type epitaxial structures or P-type epitaxial structures. In some embodiments, the N-type epitaxial structures may include SiAs, SiC, SiCP, the like, or a combination thereof. The N-type epitaxial structures may be doped with N-type dopants, such as phosphorus (P), arsenic (As), or antimony (Sb), or the like. The P-type epitaxial structures may include SiGe, SiGeB, GeB, SiGeSnB, the like, or a combination thereof. The P-type epitaxial structures may be doped with P-type dopants, such as boron (B), gallium (Ga), indium (In), aluminium (Al), or the like.

The FTV cell 10 includes a dielectric structure 150 disposed over the substrate 100, laterally surrounding the gate structures 170, and covering the source/drain epitaxy structures 140. In some embodiments, the dielectric structure 150 may include a contact etch stop layer (ESL) 155 and an interlayer dielectric (ILD) layer 152 over the CESL 155. In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide.

The FTV cell 10 includes source/drain contacts 160 in the dielectric structure 150 and in contact with the corresponding source/drain epitaxy structures 140. In some embodiments, the source/drain contacts 160 may include suitable conductive material, such as tungsten (W), ruthenium (Ru), aluminum (Al), tantalum (Ta), titanium (Ti), ruthenium (Ru), titanium nitride (TiN), tantalum nitride (TaN), tungsten nitride (WN), alloys thereof, combinations thereof, and the like.

The FTV cell 10 includes a plurality of dielectric gates 175 having a lengthwise direction along the second direction (e.g., Y-direction). In some embodiments, the dielectric gates 175 may be parallel to the gate structures 170. In some embodiments, the dielectric gates 175 may be formed of silicon oxide, silicon nitride, silicon oxynitride, combinations thereof. In some embodiments, the dielectric gates 175 and the gate structures 170 may include similar pattern, and can also be referred to as gate pattern structures. In some embodiments, an entirety of the dielectric gate 175 may be made of a dielectric material. That is, the dielectric gate 175 may be free of a metal element.

The FTV cell 10 includes a plurality of dielectric structures 180 having a lengthwise direction along the first direction (e.g., X-direction). In some embodiments, each of the dielectric structures 180 may cut the gate structures 170, so as to divide each of the gate structures 170 into several portions (see FIG. 1D). In some embodiments, the dielectric structures 180 may also cut the source/drain contacts 160, so as to divide each of the source/drain contacts 160 into several portions (see FIG. 1E). In some embodiments, the dielectric structures 180 may be formed of silicon oxide, silicon nitride, silicon oxynitride, combinations thereof. In some embodiments, the dielectric structures 180 can also be referred to as gate-cut dielectric structures.

The FTV cell 10 includes a front side interconnect structure 200. In some embodiments, the front side interconnect structure 200 may include dielectric layers 202 and 204 stacked one above another. Conductive vias 204 are disposed in the dielectric layer 202. In some embodiments, portions of the conductive vias 202 may be electrically connected with the gate structures 170, and can be referred to as gate vias. On the other hand, portions of the conductive vias 202 may be electrically connected with the source/drain contacts 160, and can be referred to as source/drain vias. Metal lines 214 are disposed in the dielectric layer 212. In some embodiments, the metal lines 214 may be electrically connected with the respective conductive vias 204. It is understood that, the front side interconnect structure 200 of FIGS. 1B to 1E are merely used to explain. More layers of dielectric layers and conductive features (e.g., conductive vias or metal lines) may also be applied in other embodiments.

In some embodiments, the dielectric layers 202 and 204 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide. In some embodiments, the conductive vias 204 and the metal lines 214 may include conductive materials, such as W, Al, Cu, Ru, Ni, Co, alloys of these, combinations thereof, and the like.

The FTV cell 10 includes two feed-trough-vias FTV_1 and FTV_2 disposed in the substrate 100. In greater detail, the feed-trough-vias FTV_1 and FTV_2 may extend from the backside of the substrate 100 toward the front side of the substrate 100, and may be electrically connected to the corresponding conductive structures on the front side of the substrate 100. In some embodiments, the feed-trough-vias FTV_1 and FTV_2 may include conductive material, such as tungsten (W), cobalt (Co), copper (Cu), the like or combinations thereof.

With respect to the top view of FIG. 1A, each of the feed-trough-vias FTV_1 and FTV_2 may include a lengthwise direction along the first direction (e.g., X-direction). Moreover, each of the feed-trough-vias FTV_1 and FTV_2 at least overlaps with the gate structures 170 and the source/drain contacts 160. For example, the each of the feed-trough-vias FTV_1 and FTV_2 may overlaps three gate structures 170 and four source/drain contacts 160, while the disclosure is not limited thereto. In some embodiments, an isolation structure 180 is between the feed-trough-vias FTV_1 and FTV_2. In some embodiments, two adjacent isolation structures 180 and two adjacent dielectric gates 175 may enclose the feed-trough-via FTV_1 or the feed-trough-via FTV_2.

With respect to the cross-sectional view of FIG. 1C, the substrate 100 and the isolation structure 105 may laterally surround lower portion of the feed-trough-via FTV_1. The feed-trough-via FTV_1 is in contact with the gate structures 170 and the source/drain contacts 160. In some embodiments, the interface between the feed-trough-via FTV_1 and the gate structure 170 is at a level lower than the interface between the feed-trough-via FTV_1 and the source/drain contact 160. In some embodiments, a height difference H1 between the interface of the feed-trough-via FTV_1 and the gate structure 170 and the interface of the feed-trough-via FTV_1 and the source/drain contact 160 is in a range from about 2 nm to about 50 nm. Stated another way, the gate structures 170 are embedded in the feed-trough-via FTV_1 in the cross-sectional view of FIG. 1C. The feed-trough-via FTV_1 may also be in contact with the dielectric structure 150 and the gate spacers 115. In some embodiments, the interface between the feed-trough-via FTV_1 and the gate structure 170 is at a level lower than the interface between the feed-trough-via FTV_1 and the dielectric structure 150 and the interface between the feed-trough-via FTV_1 and the gate spacers 115.

In some embodiments, a pair of dielectric gates 175 is disposed on opposite sides of the feed-trough-via FTV_1 in the cross-sectional view of FIG. 1C. In the FTV cell 10, the number of the dielectric gates 175 may be the same or more than the number of the feed-trough-vias (e.g., 2 in this case). Similarly, the isolation structure 105 may include two portions on opposite sides of the feed-trough-via FTV_1, and the substrate 100 may also include two portions on opposite sides of the feed-trough-via FTV_1. A gate spacer 115 may be laterally between the feed-trough-via FTV_1 and a corresponding one of the dielectric gates 175. In some embodiments, the feed-trough-via FTV_1 may be in contact with the work function metal layer 174 of the gate structure 170, while the disclosure is not limited thereto. In other embodiments, the feed-trough-via FTV_1 may be in contact with the gate filling metal 176 of the gate structure 170.

The feed-trough-via FTV_2 may also include the some cross-sectional view as the feed-trough-via FTV_1 as shown in FIG. 1C, and thus relevant detail will not be repeated for brevity.

With respect to the cross-sectional view of FIG. 1D, both of the feed-trough-vias FTV_1 and FTV_2 are in contact with the gate structure 170. In some embodiments, the feed-trough-vias FTV_1 and FTV_2 may be in contact with the work function metal layer 174 of the gate structure 170, while the disclosure is not limited thereto. In other embodiments, the feed-trough-vias FTV_1 and FTV_2 may be in contact with the gate filling metal 176 of the gate structure 170. In some embodiments, the top surfaces of the feed-trough-vias FTV_1 and FTV_2 may be higher than the top surface of the isolation structure 105 in the cross-sectional view of FIG. 1D.

Two isolation structures 180 are on opposite sides of the feed-trough-via FTV_1 or on opposite sides of the feed-trough-via FTV_2. That is, in a FTV cell 10, the number of the isolation structures 180 may be greater than the number of the feed-trough-vias FTV_1 and FTV_2. For example, in the present embodiments, there are two feed-trough-vias, and thus at least three isolation structures 180 may be applied. In some embodiments, the top surfaces of the isolation structures 180 may be higher than the top surfaces of the feed-trough-vias FTV_1 and FTV_2, and the bottom surfaces of the isolation structures 180 may be lower than the top surfaces of the feed-trough-vias FTV_1 and FTV_2.

With respect to the cross-sectional view of FIG. 1E, both of the feed-trough-vias FTV_1 and FTV_2 are in contact with the source/drain contacts 160. In some embodiments, the dielectric structure 150 may be in contact with sidewalls of the feed-trough-vias FTV_1 and FTV_2. Moreover, the CESL 155 and the ILD layer 152 may both be in contact with the sidewalls of the feed-trough-vias FTV_1 and FTV_2. In some embodiments, the top surfaces of the feed-trough-vias FTV_1 and FTV_2 may be lower than the top surfaces of the source/drain epitaxy structures 140.

The FTV cell 10 includes a backside interconnect structure 300. In some embodiments, the backside interconnect structure 300 may include a dielectric layer 302. Metal lines 304 are disposed in the dielectric layer 302. In some embodiments, the metal lines 304 may be electrically connected with the respective feed-trough-vias FTV_1 and FTV_2. It is understood that, the backside interconnect structure 300 of FIGS. 1B to 1E are merely used to explain. More layers of dielectric layers and conductive features (e.g., conductive vias or metal lines) may also be applied in other embodiments. In some embodiments, the metal lines 304 may be backside power rails, and thus the feed-trough-vias FTV_1 and FTV_2 may be configured to transmit power and signal between the backside interconnect structure 300 and the front side interconnect structure 200.

In some embodiments, the dielectric layers 302 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide. In some embodiments, the metal lines 304 may include conductive materials, such as W, Al, Cu, Ru, Ni, Co, alloys of these, combinations thereof, and the like.

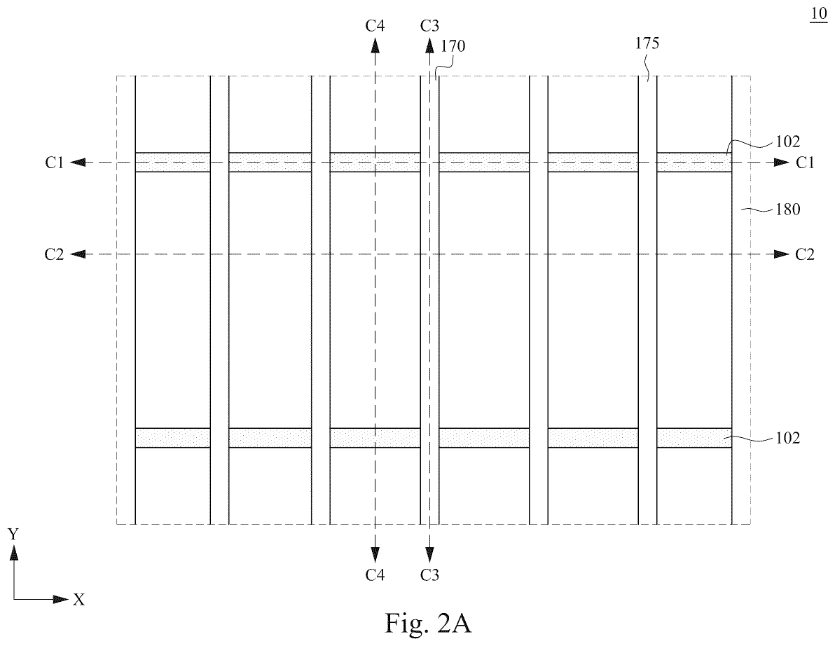

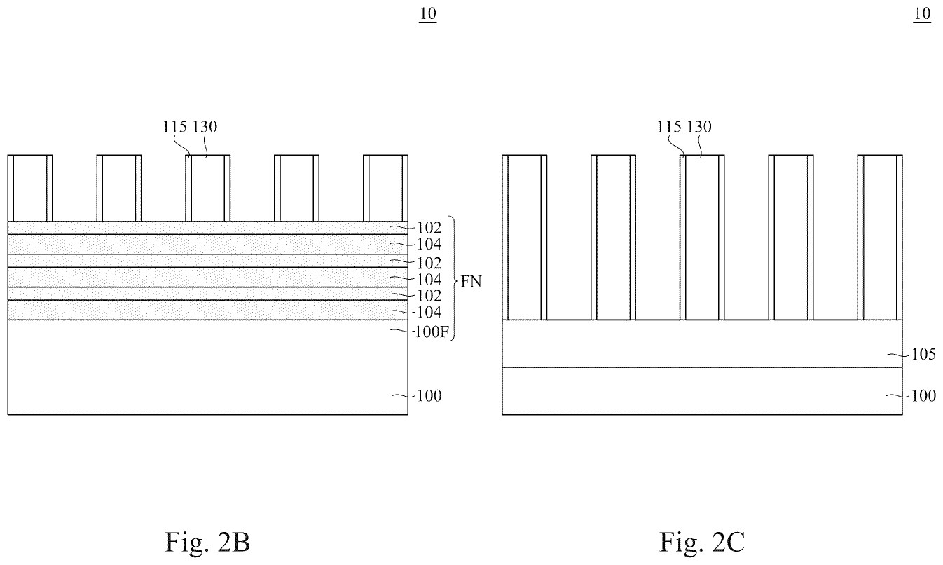

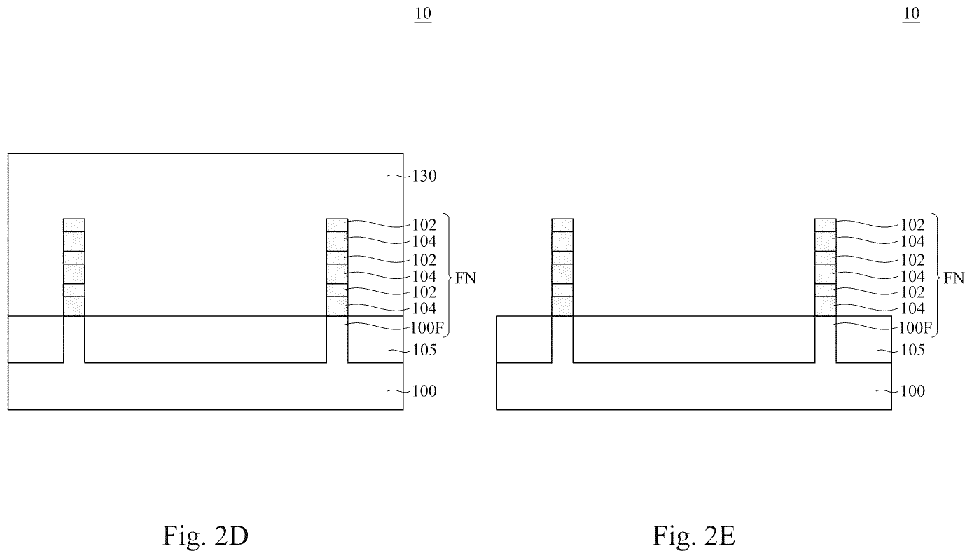

FIGS. 2A to 8E illustrate a method in various stages of forming a semiconductor device in accordance with some embodiments of the present disclosure. In greater detail, FIGS. 2A to 8E illustrate a method for forming the FTV cell 10 as discussed in FIGS. 1A to 1E. Some elements of FIGS. 2A to 8E have been described with respect to FIGS. 1A to 1E, and thus relevant details will not be repeated for brevity. Although FIGS. 2A to 8E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 2A to 2E, in which FIG. 2A is a top view of a semiconductor device, and FIGS. 1B, 1C, 1D, and 1E are cross-sectional views along lines C1-C1, C2-C2, C3-C3, and C4-C4 of FIG. 2A, respectively. A stack of alternating semiconductor layers 102 and semiconductor layers 104 are formed over a substrate 100. In some embodiments, the semiconductor layers 102 may be made of pure silicon layers that are free of germanium. The semiconductor layers 102 may also be substantially pure silicon layers, for example, with a germanium percentage lower than about 1 percent. The semiconductor layers 104 may be made of silicon germanium. For example, the germanium percentage (atomic percentage concentration) of the semiconductor layers 104 may be in a range from about 20 percent and about 40 percent. In some embodiments, the semiconductor layers 102 and 104 may be deposited using suitable deposition process, such as selective epitaxial growth (SEG), chemical vapor deposition (CVD), molecular beam epitaxy (MBE), or other suitable process(es). In some embodiments, the semiconductor layers 104 will be removed during a replacement gate (RPG) process, and may also be referred to as sacrificial layers 104.

The stack of alternating semiconductor layers 102 and semiconductor layers 104 and the substrate 100 may be patterned to form fin structures FN. Each of the fin structure FN includes the stack of alternating semiconductor layers 102 and 104, and a semiconductor fin 100F of the substrate 100.

Once the fin structures FN are formed, isolation structure 105 is formed over the substrate 100 and laterally surrounding the semiconductor fins 100F of the fin structures FN. In some embodiments, the isolation structure 105 may be formed by, for example, depositing a dielectric material blanket over the substrate 100, performing a planarization process to remove excess material of the dielectric material until the fin structures FN are exposes, and then etching back the dielectric material to a desired position.

Dummy gate structures 130 are formed over the substrate 100 and crossing the fin structures FN, respectively. In some embodiments, each of the dummy gate structures 130 includes a dummy gate dielectric and a dummy gate electrode over the dummy gate dielectric. The dummy gate dielectric may be, for example, silicon oxide, silicon nitride, a combination thereof, or the like, and may be deposited or thermally grown according to acceptable techniques. The dummy gate electrode may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

Gate spacers 115 are formed on opposite sidewalls of the dummy gate structures 130. In some embodiments, the gate spacers 115 may be formed by, for example, depositing a spacer material blanket over the substrate 100, and then performing an anisotropic etching to remove horizontal portions of the spacer material, leaving vertical portions of the spacer material on sidewalls of the dummy gate structures 130 as the gate spacers 115.

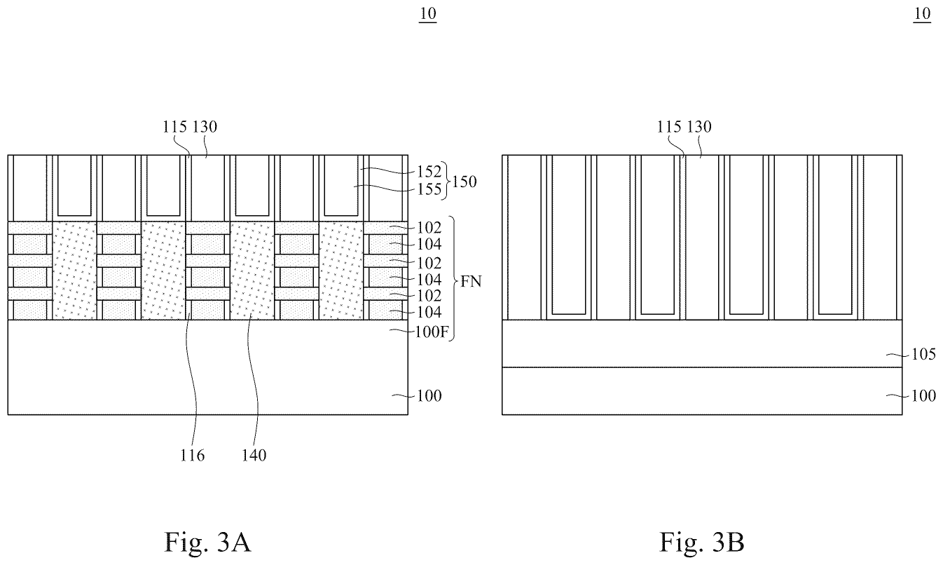

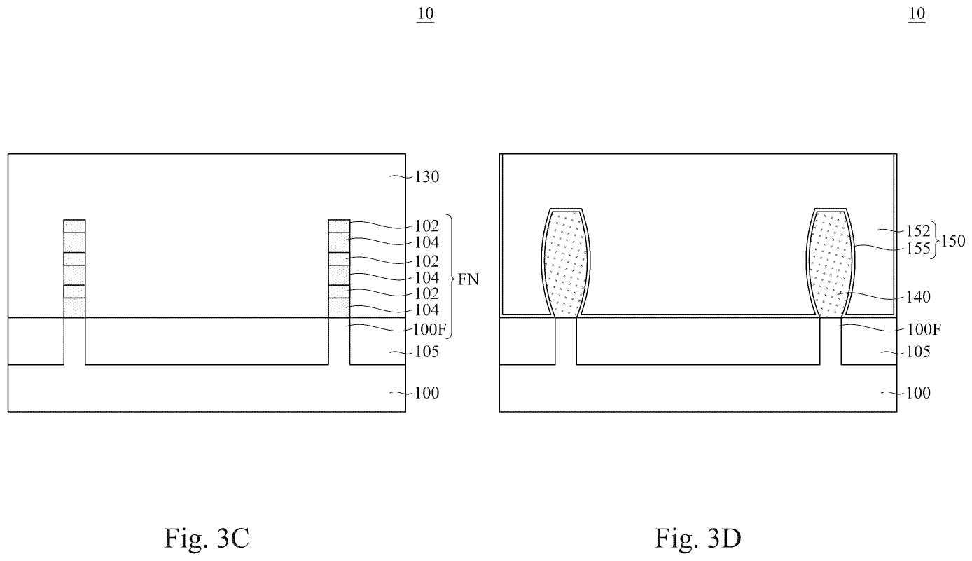

Reference is made to FIGS. 3A to 3D, in which FIGS. 3A to 3D follow the cross-sectional views of FIGS. 2B to 2E, respectively. An etching process is performed to remove portions of the fin structures FN by using the dummy gate structures 130 and the gate spacers 115 as etch mask, so as to form source/drain openings in the fin structures FN. In some embodiments, the etching process may be wet etch, dry etch, or combinations thereof.

After the source/drain openings are formed, inner spacers 116 are formed on opposite ends of each of the semiconductor layers 104. The inner spacers 116 can be formed by, for example, performing an etching process to laterally etch the semiconductor layers 104 to form sidewall recesses, depositing a dielectric material blanket over the substrate 100 and filling the sidewall recesses, and then performing an anisotropic etching to remove portions of the dielectric material outside the sidewall recesses, leaving the remaining portions of the dielectric material in the sidewall recesses as the inner spacers 116.

Source/drain epitaxy structures 140 are formed on opposite ends of the exposed semiconductor layer 102, and on top surface of the exposed semiconductor fins 100F. In some embodiments, the source/drain epitaxy structures 140 may be formed by a selective epitaxial growth (SEG) process. The SEG process may selectively grow a semiconductor material on exposed semiconductor surfaces, such as the exposed surfaces of the semiconductor layer 102 and the exposed surfaces of the semiconductor fins 100F.

A contact etch stop layer (CESL) 155 is formed covering the source/drain epitaxy structures 140. Afterwards, an interlayer dielectric (ILD) layer 152 is formed over the CESL 155. Then, a planarization process, such as CMP, is performed to remove excess materials of the CESL 155 and the ILD 152 until the dummy gate structures 130 are exposed.

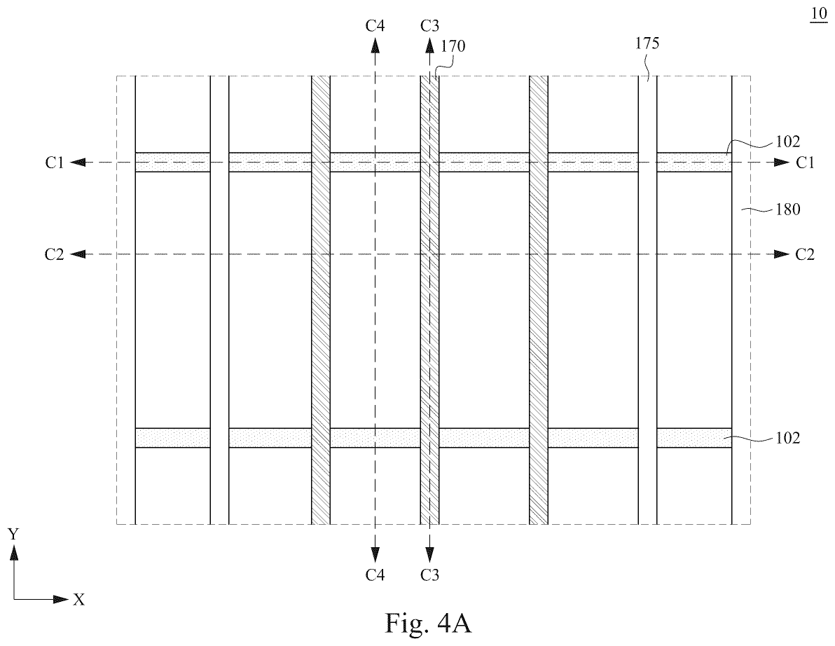

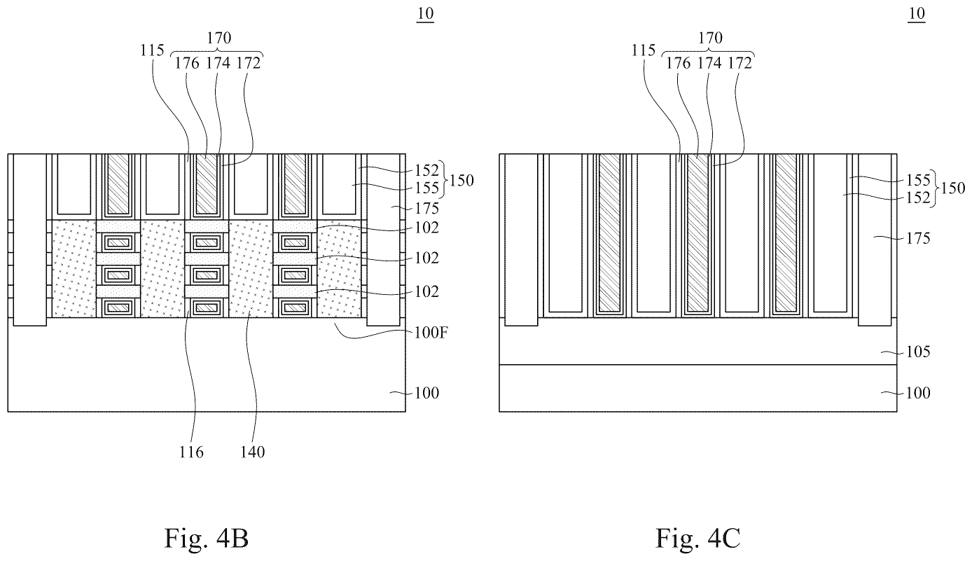

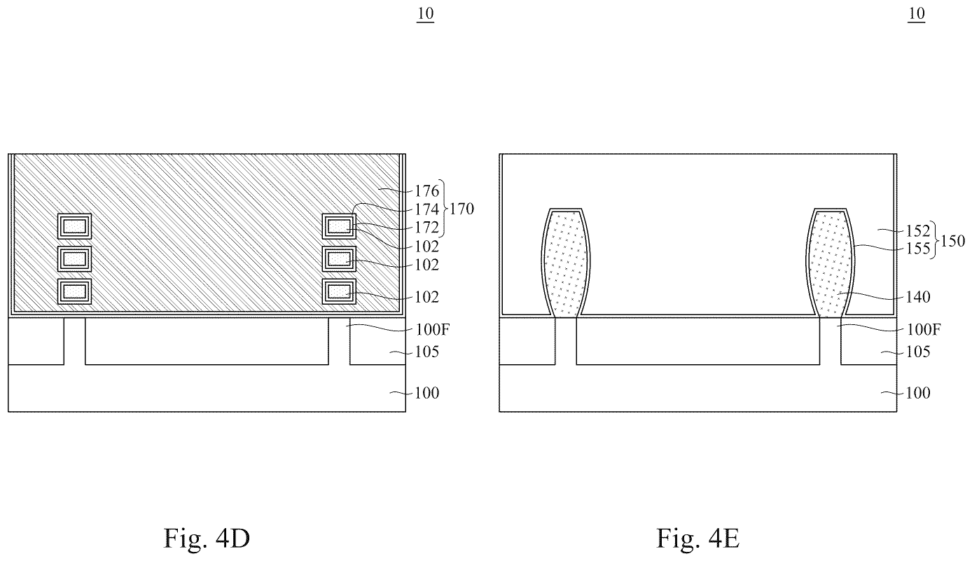

Reference is made to FIGS. 4A to 4E, in which FIG. 4A is a top view of a semiconductor device, and FIGS. 4B, 4C, 4D, and 4E are cross-sectional views along lines C1-C1, C2-C2, C3-C3, and C4-C4 of FIG. 4A, respectively. Portions of the dummy gate structures 130 are replaced with gate structures 170, and portions of the dummy gate structures 130 are replaced with dielectric gates 175. In some embodiments, the gate structures 170 and the dielectric gates 175 may be formed at different time points.

With respect to the gate structures 170, first portions of the dummy gate structures 130 are removed to form first gate trenches between the gate spacers 115. Then, an etching process is performed to remove the semiconductor layers 104, such that the semiconductor layers 102 are suspended over the substrate 100. Then, a gate dielectric layer 172, a work function metal layer 174, and a gate filling metal 176 are sequentially deposited in the gate trenches GT1. A planarization process may be performed to the gate structures 170 until the dielectric structure 150 is exposed.

With respect to the dielectric gates 175, second portions of the dummy gate structures 130 removed to form second gate trenches between the gate spacers 115. An anisotropic etching may be performed through the second gate trenches, so as to remove the semiconductor layers 102 and 104 through the second gate trenches. Then, the dielectric gates 175 are formed in the second gate trenches by filling the second gate trenches with dielectric material(s). A planarization process may be performed to the dielectric gates 175 until the dielectric structure 150 is exposed.

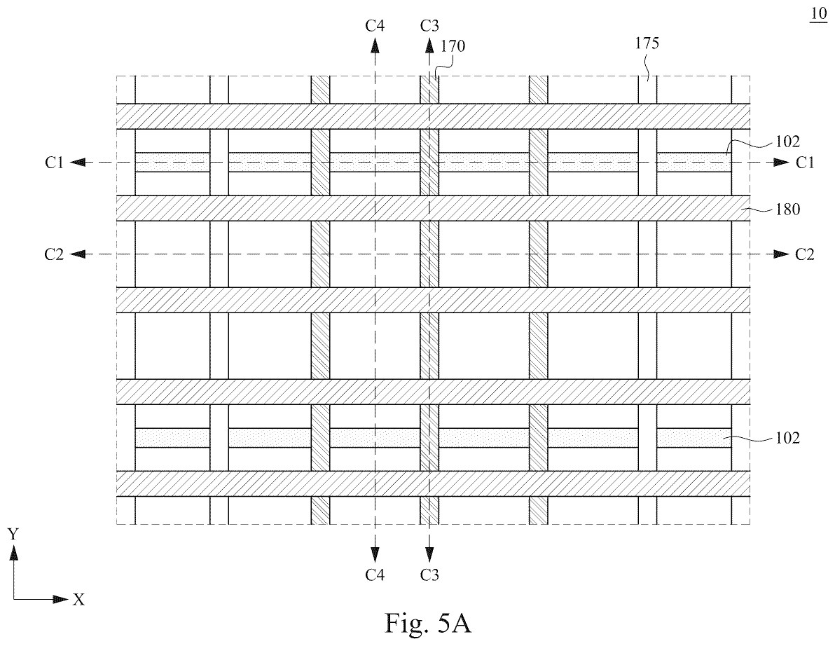

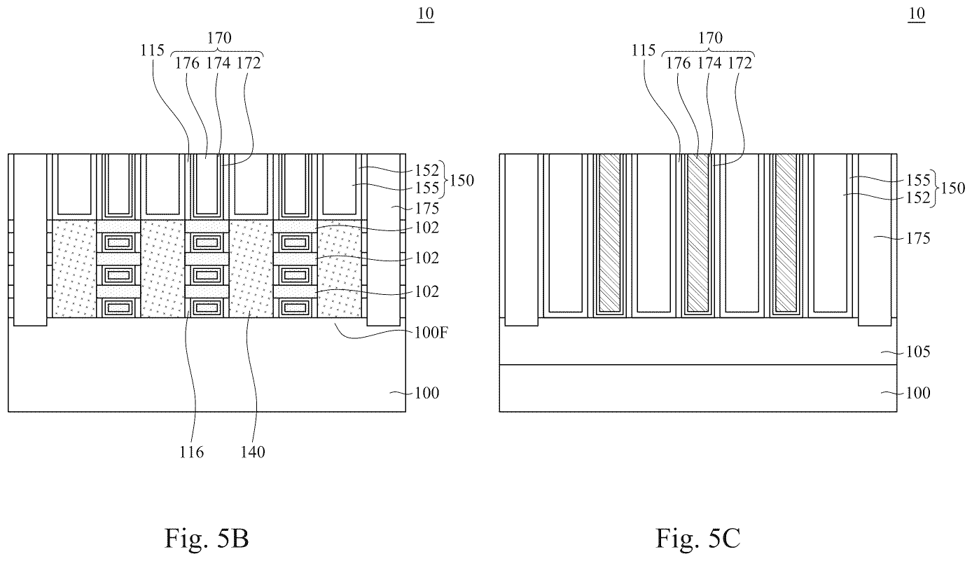

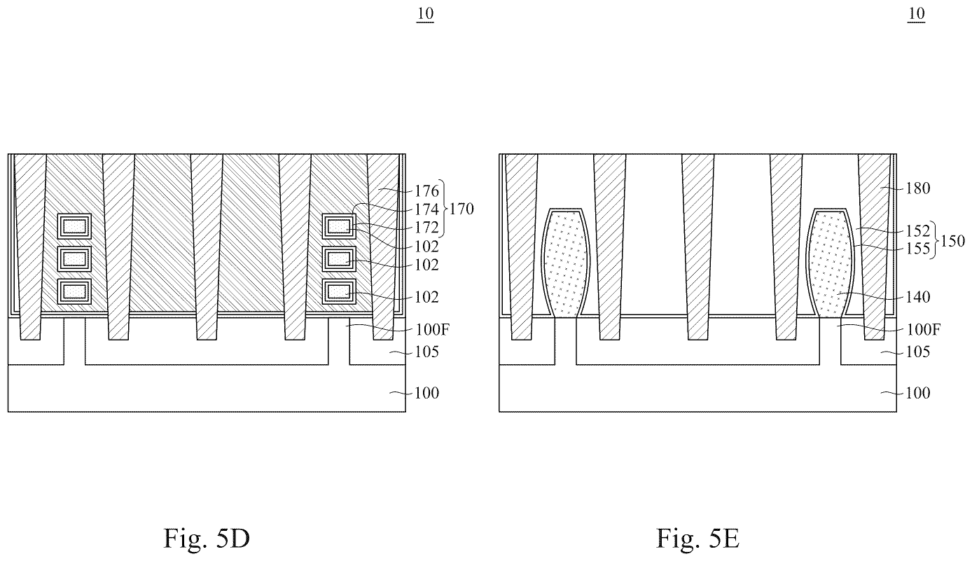

Reference is made to FIGS. 5A to 5E, in which FIG. 5A is a top view of a semiconductor device, and FIGS. 5B, 5C, 5D, and 5E are cross-sectional views along lines C1-C1, C2-C2, C3-C3, and C4-C4 of FIG. 5A, respectively. Isolation structures 180 are formed over the substrate 100 and cutting the gate structures 170 and the dielectric gates 175. The isolation structures 180 may be formed by, for example, patterning the gate structures 170, the dielectric structure 150, and the dielectric gates 175 to form openings therein, and then filling the openings with dielectric material(s). A planarization process may be performed to the isolation structures 180 until the dielectric structure 150 is exposed.

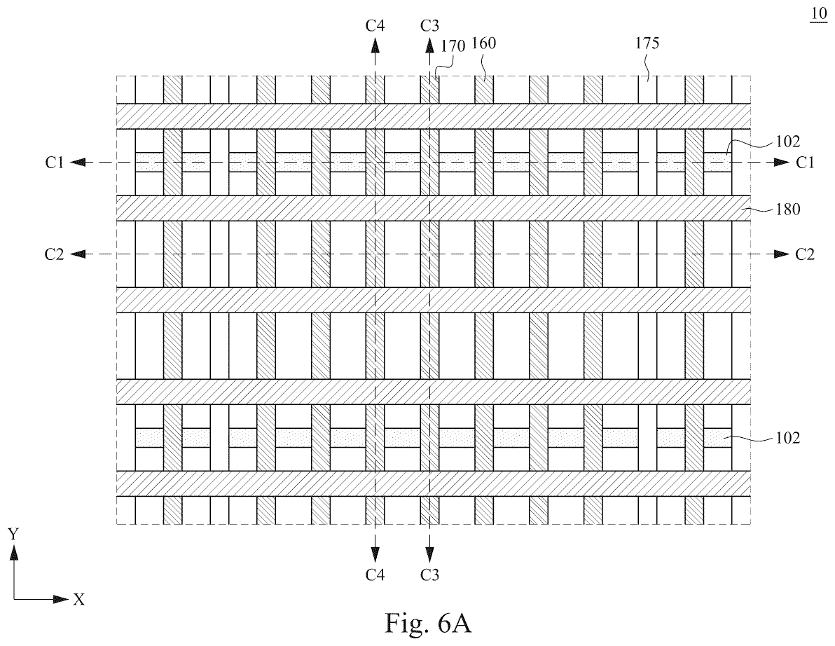

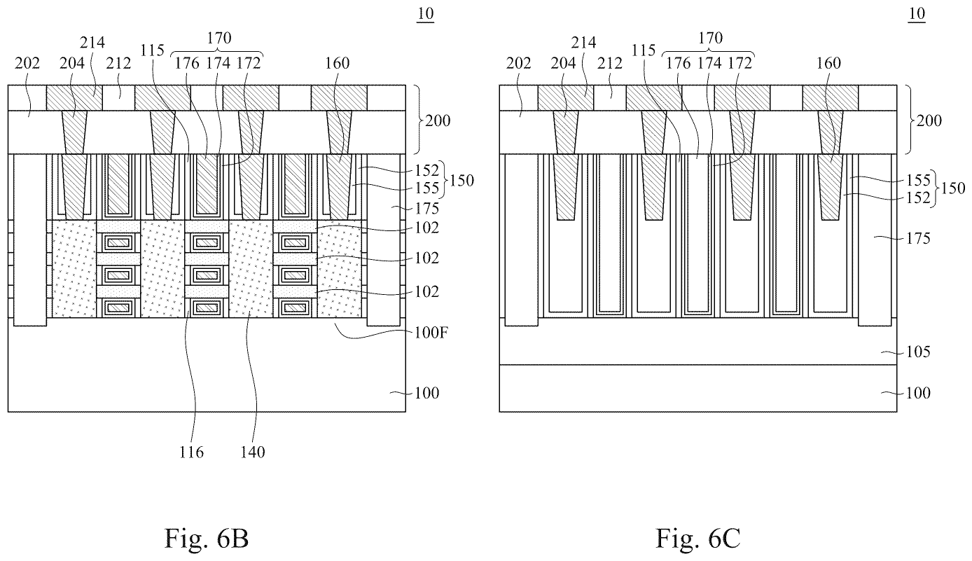

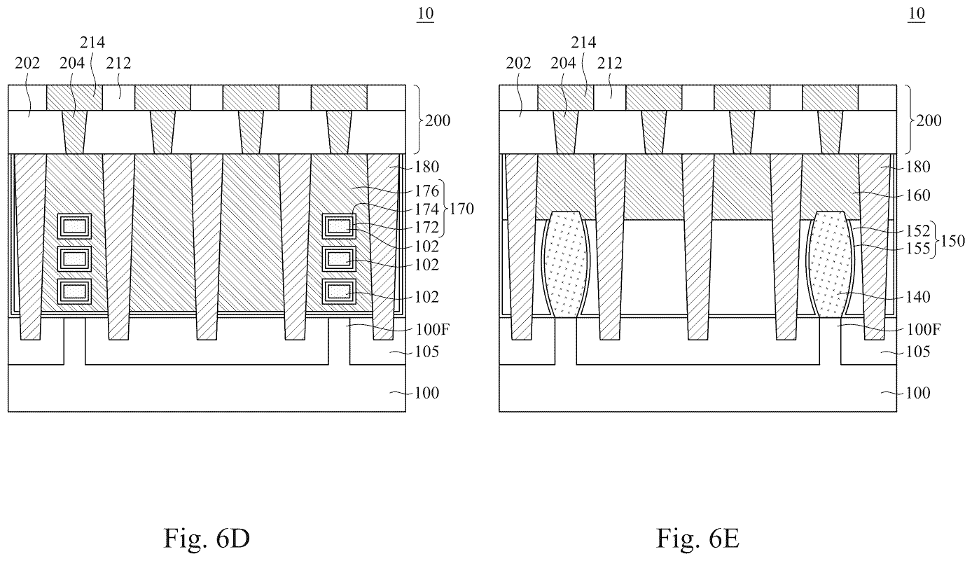

Reference is made to FIGS. 6A to 6E, in which FIG. 6A is a top view of a semiconductor device, and FIGS. 6B, 6C, 6D, and 6E are cross-sectional views along lines C1-C1, C2-C2, C3-C3, and C4-C4 of FIG. 6A, respectively. Source/drain contacts 160 are formed in the dielectric structure 150 and in contact with the corresponding source/drain epitaxy structures 140. In some embodiments, the source/drain contacts 160 may be formed by, for example, patterning the dielectric structure 150 to form openings that expose the source/drain epitaxy structures 140, and then filling the openings with conductive material(s). A planarization process may be performed to the source/drain contacts 160 until the dielectric structure 150 is exposed. In some embodiments, the source/drain contacts 160 may be formed prior to forming the isolation structures 180.

After the source/drain contacts 160 are formed, a front side interconnect structure 200 is formed over the dielectric structure 150 and electrically connected with the source/drain contacts 160. In some embodiments, the front side interconnect structure 200 may be formed by, for example, forming a dielectric layer 202 over the dielectric structure 150, forming the conductive vias 204 in the dielectric layer 202, forming the dielectric layer 212 over the dielectric layer 202, and then forming the metal lines 214 in the dielectric layer 212.

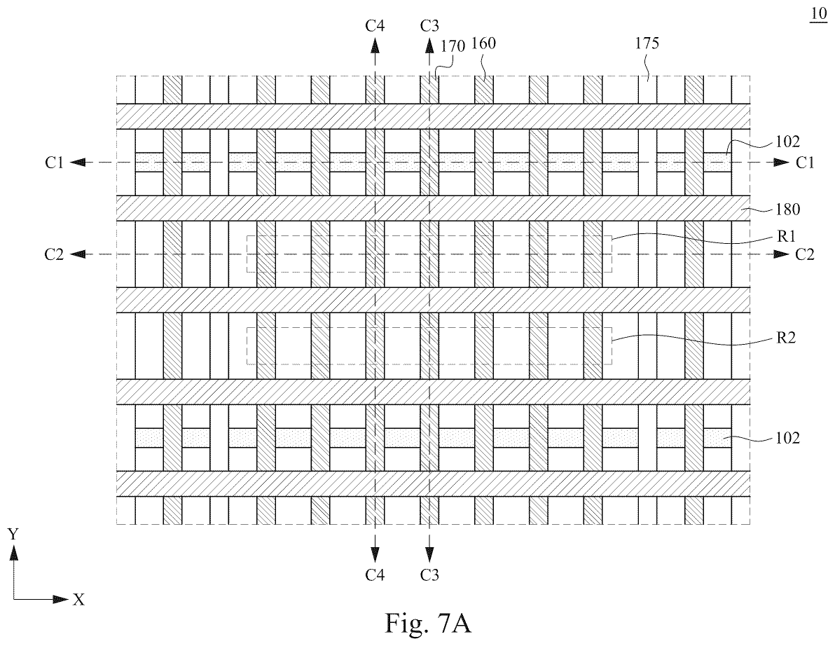

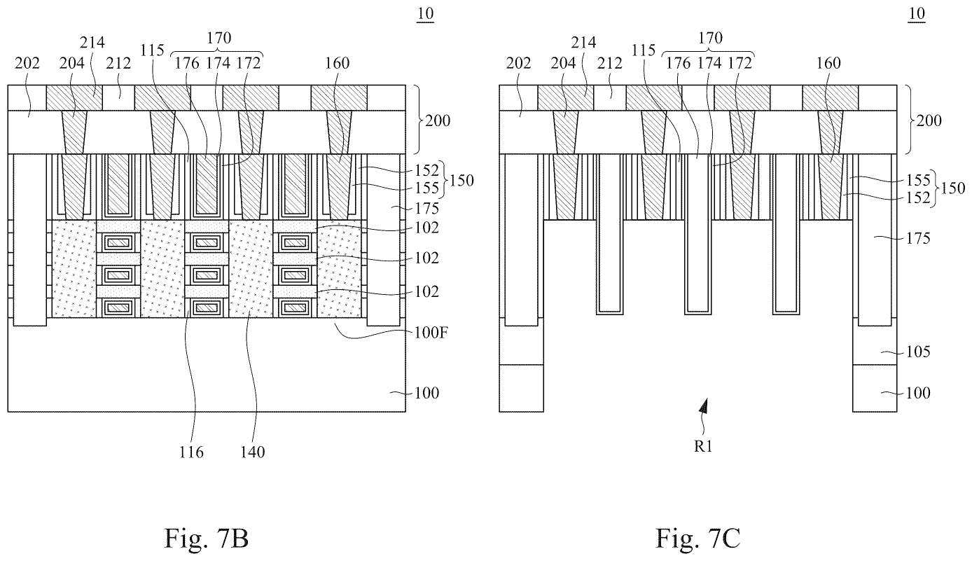

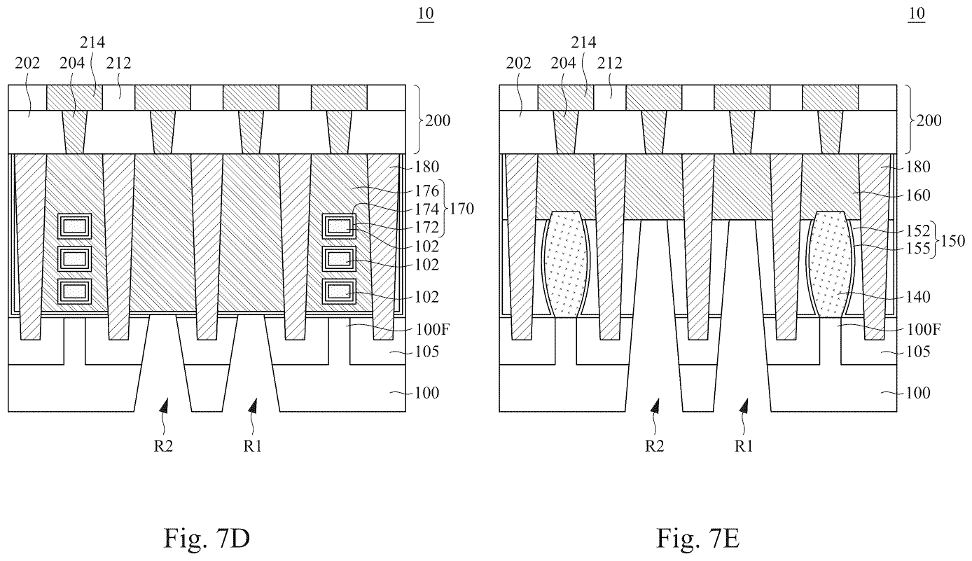

Reference is made to FIGS. 7A to 7E, in which FIG. 7A is a top view of a semiconductor device, and FIGS. 7B, 7C, 7D, and 7E are cross-sectional views along lines C1-C1, C2-C2, C3-C3, and C4-C4 of FIG. 7A, respectively. A patterning process is performed on the backside of the substrate 100, so as to form recesses R1 and R2 in the substrate 100, in which the recesses R1 and R2 may expose the source/drain contacts 160 and the gate structures 170. In some embodiments, the recesses R1 and R2 may also expose the isolation structure 105, the dielectric structure 150 and the gate spacers 115. The recesses R1 and R2 may be formed by, for example, flipping over the substrate 100, such that the backside of the substrate 100 faces upward, forming a patterned mask over the backside of the substrate 100, and then performing an etching process through the patterned mask.

As shown in the cross-sectional view of FIG. 7C, the etching process for forming the recess R1 (and recess R2) may include a higher etching rate to a dielectric material than to a metal-containing material. Accordingly, in some embodiments, the metal component of the gate structures 170 may include a higher etching resistance to the etching process. As a result, once the metal component of the gate structures 170 (e.g., the work function metal layer 174 or the gate filling metal 176) is exposed through the recesses R1 and R2, the metal component of the gate structures 170 may act as an etch stop layer to the etching process. The resulting structure is shown in FIG. 7C, the metal component of the gate structures 170 may protrude into the recess R1 (and recess R2). On the other hand, portions of the dielectric structure 150 may be removed such that the source/drain contacts 160 are exposed through the recess R1 (and recess R2).

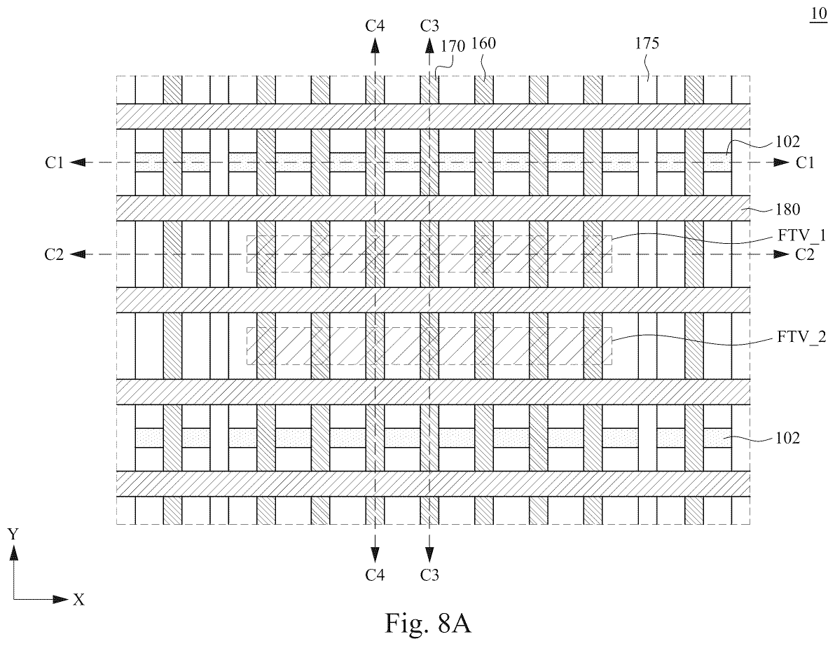

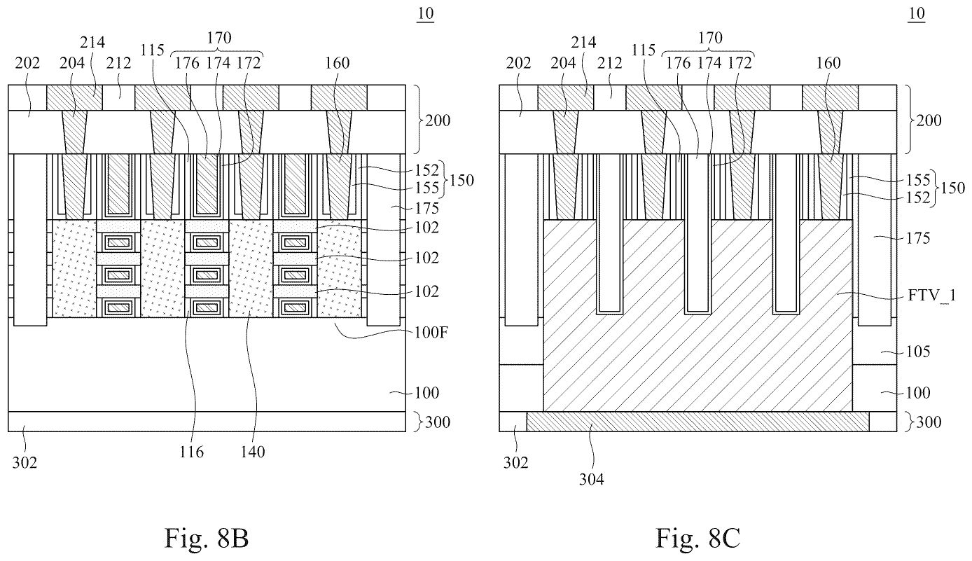

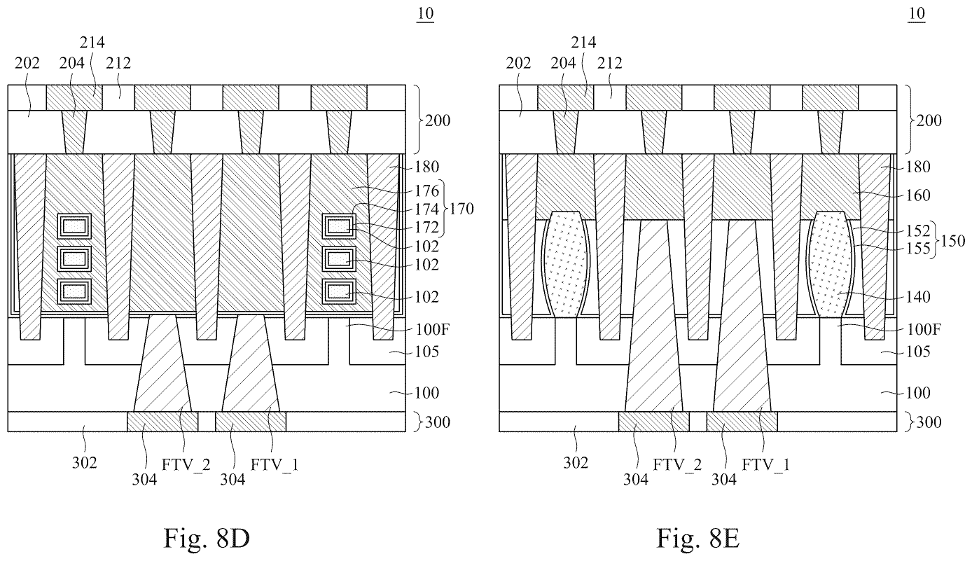

Reference is made to FIGS. 8A to 8E, in which FIG. 8A is a top view of a semiconductor device, and FIGS. 8B, 8C, 8D, and 8E are cross-sectional views along lines C1-C1, C2-C2, C3-C3, and C4-C4 of FIG. 8A, respectively. Feed-trough-vias FTV_1 and FTV_2 are formed in the recesses R1 and R2. The feed-trough-vias FTV_1 and FTV_2 may be formed by, for example, filling the recesses R1 and R2 with conductive material, and then performing a planarization process to remove excess material of the conductive material until the substrate 100 is exposed.

After the feed-trough-vias FTV_1 and FTV_2 are formed, a backside interconnect structure 300 is formed over the backside of the substrate 100 and electrically connected to the feed-trough-vias FTV_1 and FTV_2. In some embodiments, the backside interconnect structure 300 may be formed by, for example, forming a dielectric layer 302 over the backside of the substrate 100, and then forming the metal lines 304 in the dielectric layer 302.

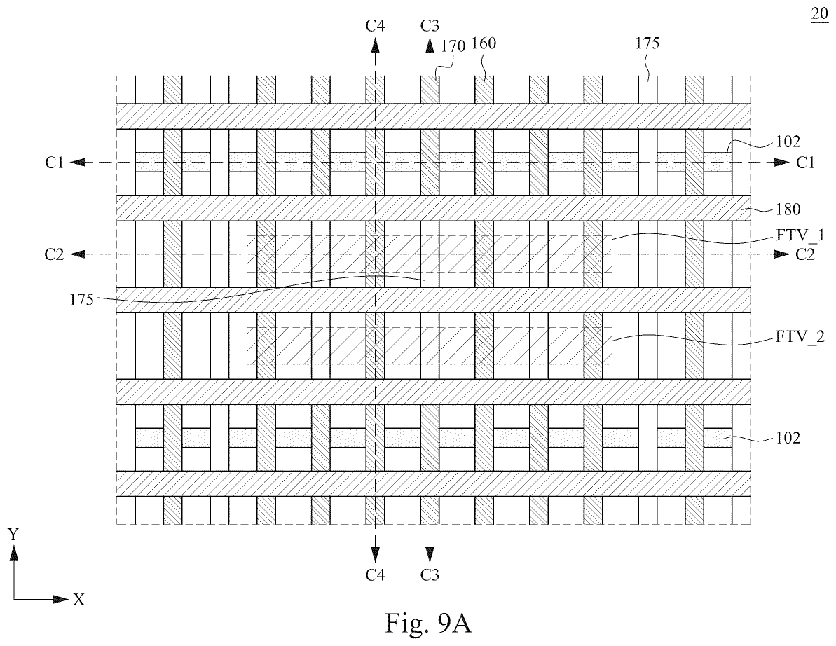

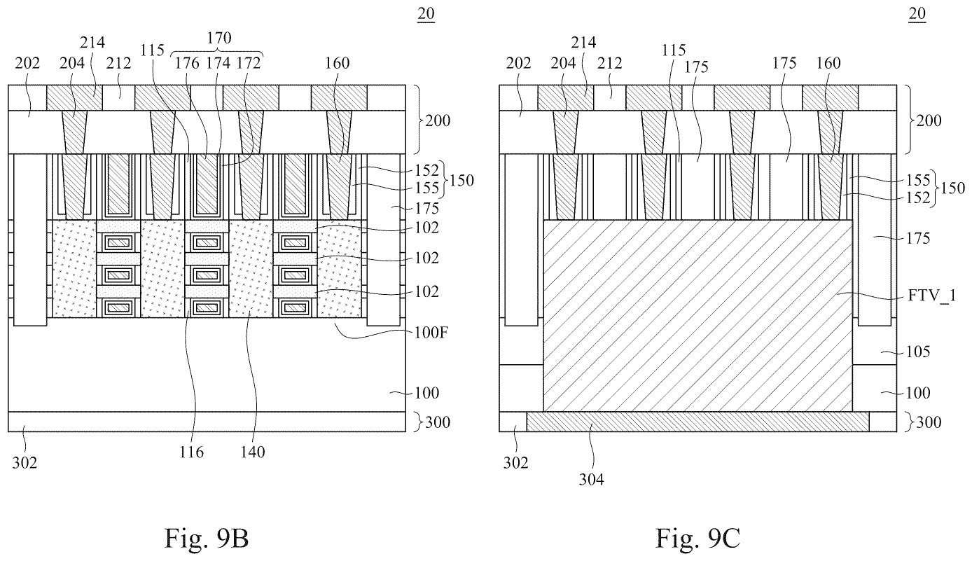

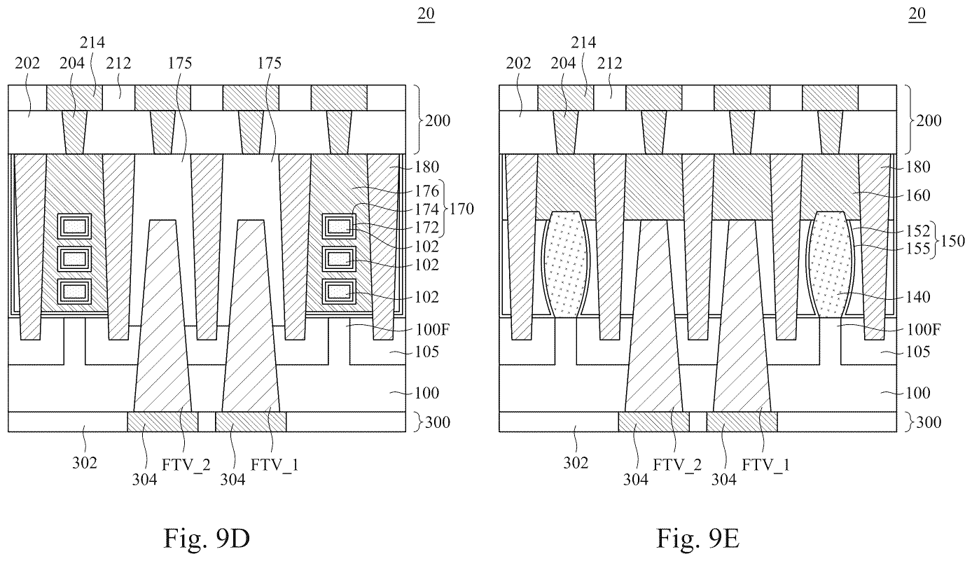

FIG. 9A is a top view of a semiconductor device in accordance with some embodiments of the present disclosure. FIGS. 9B, 9C, 9D, and 9E are cross-sectional views along lines C1-C1, C2-C2, C3-C3, and C4-C4 of FIG. 9A, respectively. It is noted that some elements in the cross-sectional views of FIGS. 9B, 9C, 9D, and 9E are not illustrated in FIG. 9A for brevity. FIGS. 9A to 9E illustrate an example of a feed-through-via (FTV) cell 20. The FTV cell 20 may be similar to the FTV cell 10 as discussed above with respect to FIGS. 1A to 1E, and relevant details will not be repeated for brevity.

The FTV cell 20 of FIGS. 9A to 9E is different from the FTV cell 10 of FIGS. 1A to 1E, in that there are dielectric gates 175 vertically overlapping with the feed-through-vias FTV_1 and FTV_2, respectively. In the cross-sectional view of FIG. 9C, the feed-through-via FTV_1 is in contact with bottom surfaces of the dielectric gates 175. In some embodiments, the interface between the feed-through-via FTV_1 and the source/drain contact 160 may be substantially level with the interface between the feed-through-via FTV_1 and the dielectric gates 175. In the cross-sectional view of FIG. 9D, the dielectric gate 175 may extend to sidewalls of the feed-through-vias FTV_1 and FTV_2, respectively. In some embodiments, the dielectric gate 175 may extend to a position laterally between the isolation structure 180 and the feed-through-via FTV_1 (or the feed-through-via FTV_2).

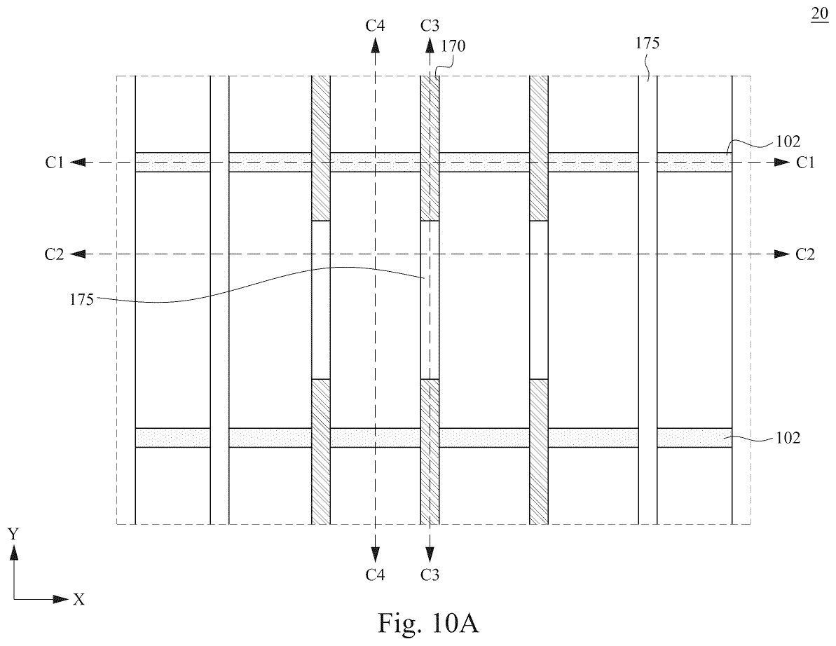

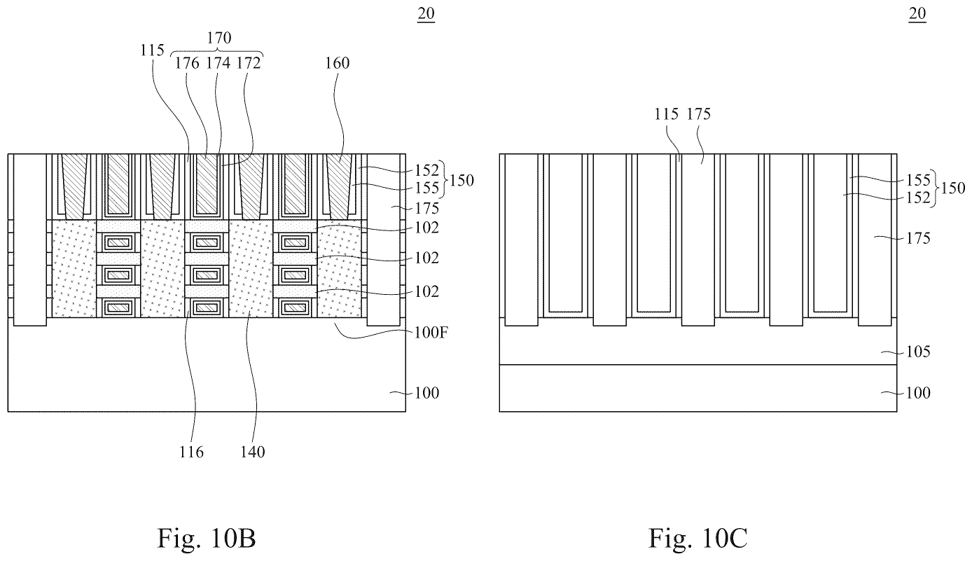

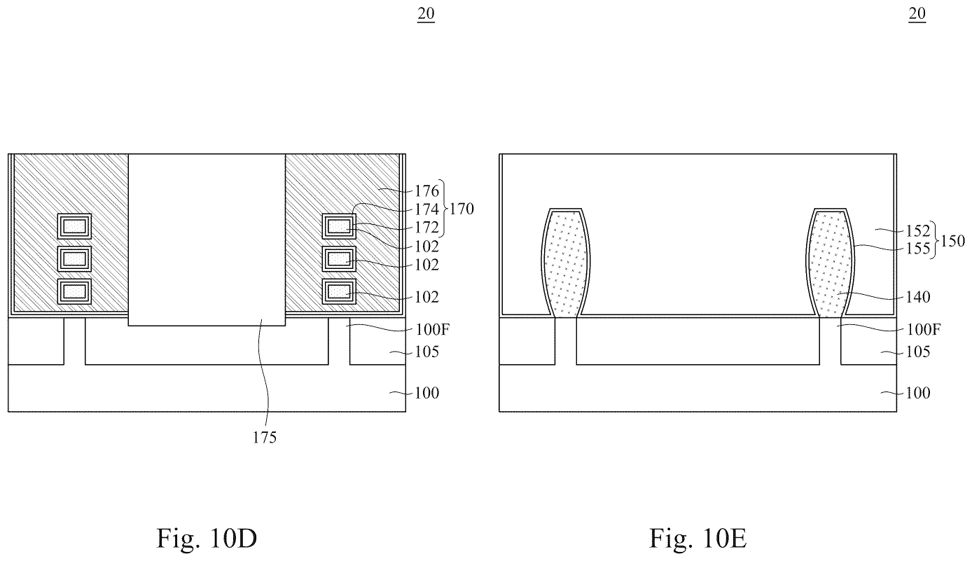

FIGS. 10A to 13E illustrate a method in various stages of forming a semiconductor device in accordance with some embodiments of the present disclosure. In greater detail, FIGS. 10A to 13E illustrate a method for forming the FTV cell 20 as discussed in FIGS. 9A to 9E. Some elements of FIGS. 10A to 13E have been described with respect to FIG. 9A to 9E, and thus relevant details will not be repeated for brevity. Although FIGS. 10A to 13E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 10A to 10E, in which FIG. 10A is a top view of a semiconductor device, and FIGS. 10B, 10C, 10D, and 10E are cross-sectional views along lines C1-C1, C2-C2, C3-C3, and C4-C4 of FIG. 10A, respectively. Portions of the dummy gate structures 130 are replaced with gate structures 170, and portions of the dummy gate structures 130 are replaced with dielectric gates 175. In some embodiments, the gate structures 170 and the dielectric gates 175 may be formed at different time points. The formation of the gate structures 170 and the dielectric gates 175 have been discussed in FIGS. 4A to 4E, and thus relevant details will not be repeated for brevity.

As shown in FIGS. 10A and 10D, different portions of a dummy gate structure 130 can be replaced with the gate structures 170 and the dielectric gates 175, respectively. For example, in some embodiments, a dummy gate structure 130 can be replaced with a dielectric gate 175 and two gate structures 170 on opposite sides of the gate structures 170.

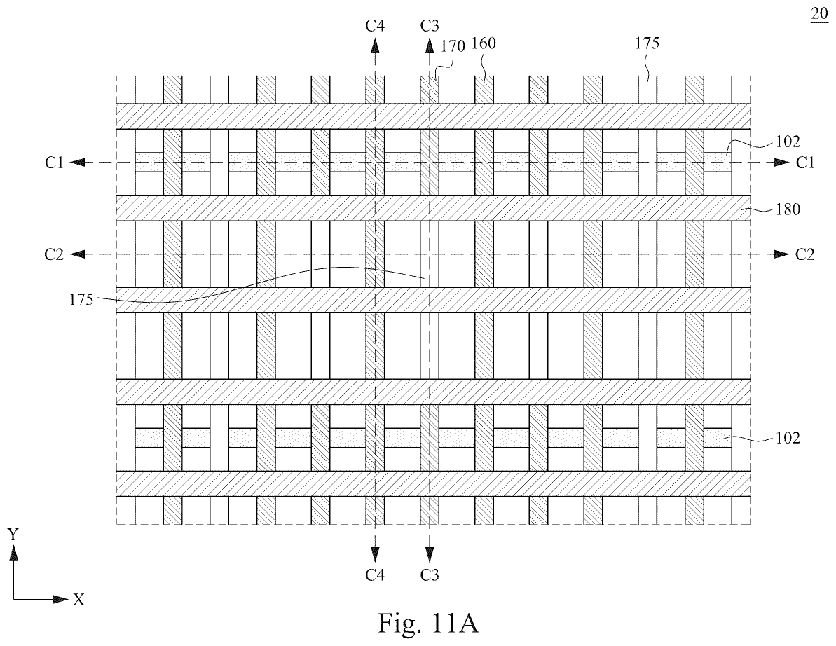

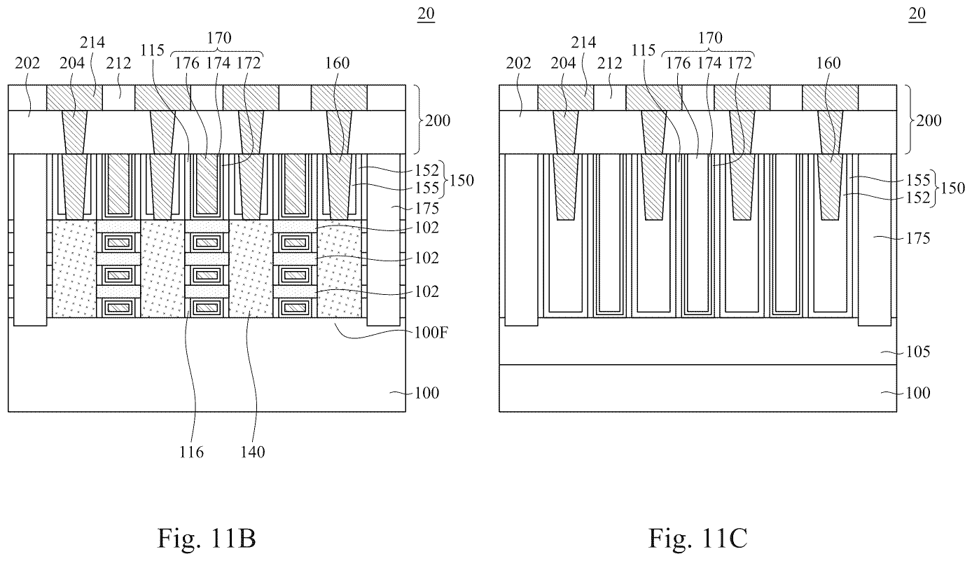

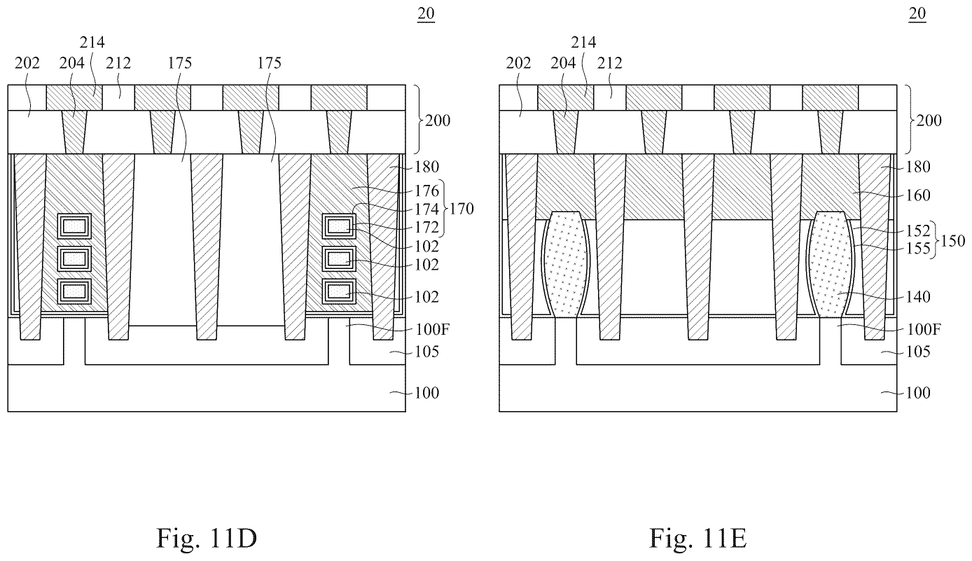

Reference is made to FIGS. 11A to 11E, in which FIG. 11A is a top view of a semiconductor device, and FIGS. 11B, 11C, 11D, and 11E are cross-sectional views along lines C1-C1, C2-C2, C3-C3, and C4-C4 of FIG. 11A, respectively. The structure of FIGS. 10A to 10E may undergo the processes as discussed in FIGS. 5A to 6E. For example, isolation structures 180 are formed over the substrate 100 and cutting the gate structures 170 and the dielectric gates 175. Source/drain contacts 160 are formed in the dielectric structure 150 and in contact with the corresponding source/drain epitaxy structures 140. After the source/drain contacts 160 are formed, a front side interconnect structure 200 is formed over the dielectric structure 150 and electrically connected with the source/drain contacts 160. As shown in FIG. 11D, a dielectric gate 175 may be cut by one isolation structure 180, and two isolation structures 180 may be formed between the dielectric gate 175 and the adjacent gate structures 170.

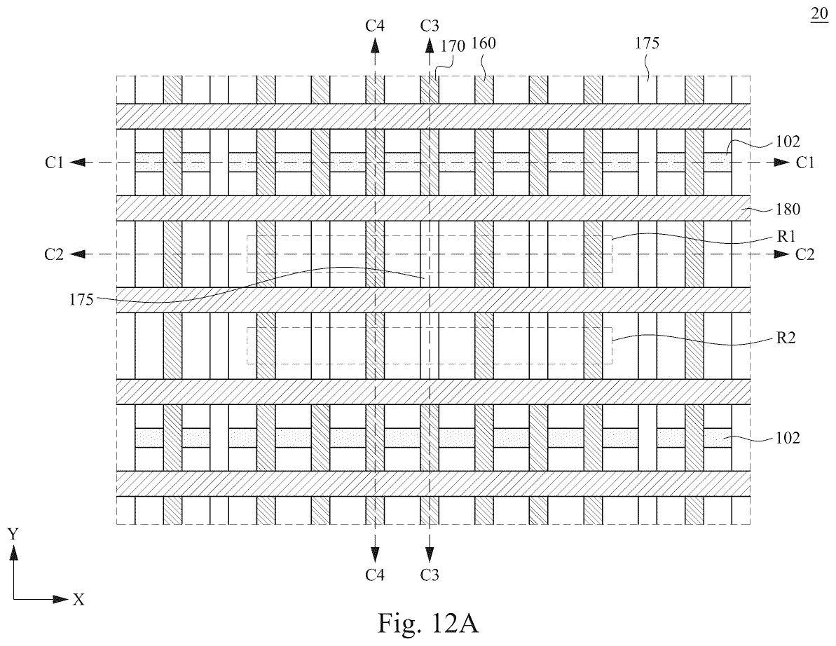

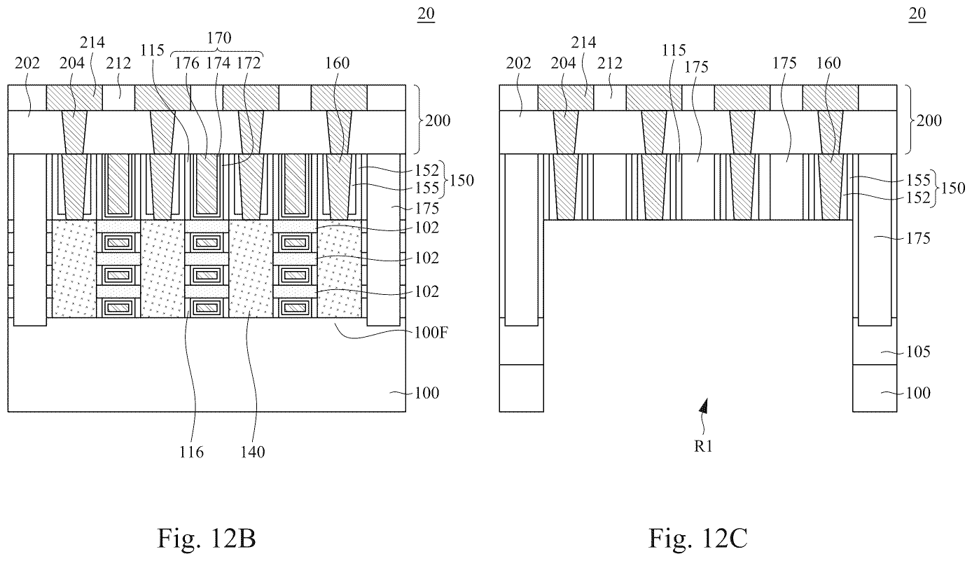

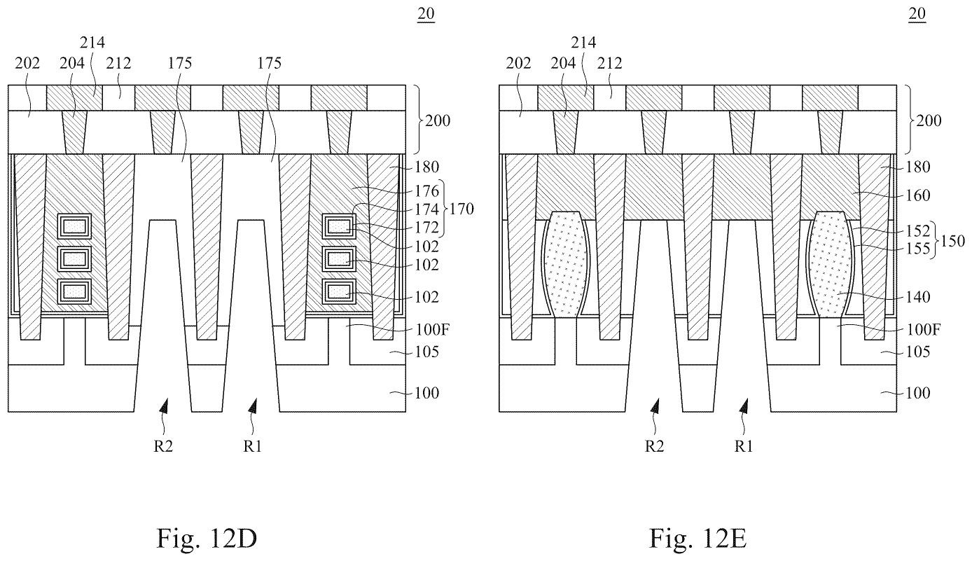

Reference is made to FIGS. 12A to 12E, in which FIG. 12A is a top view of a semiconductor device, and FIGS. 12B, 12C, 12D, and 12E are cross-sectional views along lines C1-C1, C2-C2, C3-C3, and C4-C4 of FIG. 12A, respectively. A patterning process is performed on the backside of the substrate 100, so as to form recesses R1 and R2 in the substrate 100, in which the recesses R1 and R2 may expose the source/drain contacts 160 and the dielectric gates 175. In some embodiments, the recesses R1 and R2 may also expose the isolation structure 105, the dielectric structure 150 and the gate spacers 115. The recesses R1 and R2 may be formed by, for example, flipping over the substrate 100, such that the backside of the substrate 100 faces upward, forming a patterned mask over the backside of the substrate 100, and then performing an etching process through the patterned mask.

As shown in the cross-sectional view of FIG. 12C, the etching process for forming the recess R1 (and recess R2) may include a higher etching rate to a dielectric material. Accordingly, portions of the dielectric gates 175, the dielectric structure 150, and the gate spacers 115 may be removed such that the source/drain contacts 160 are exposed through the recess R1 (and recess R2). As shown in the cross-sectional view of FIG. 12D, the recesses R1 and R2 may extend into the respective dielectric gates 175.

The process as discussed in FIGS. 12A to 12E may be similar to the process as discussed in FIGS. 7A to 7E, the difference is that in the process of FIGS. 12A to 12E, there is no metal gate structures 170 (see FIG. 7C) acting as an etch stop layer during the etching process. Accordingly, the recesses R1 and R2 may be formed with a larger window, and will be beneficial for the following formed feed-through-vias.

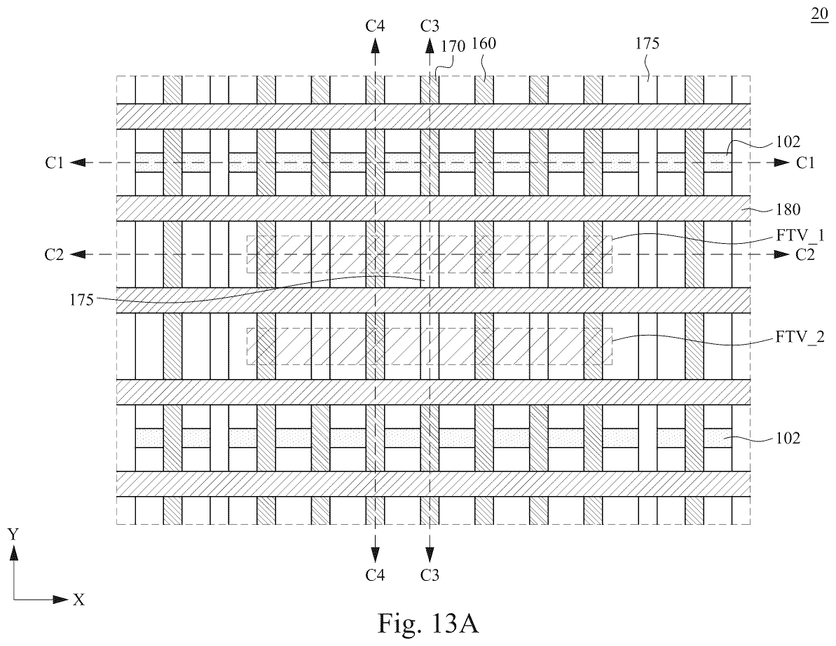

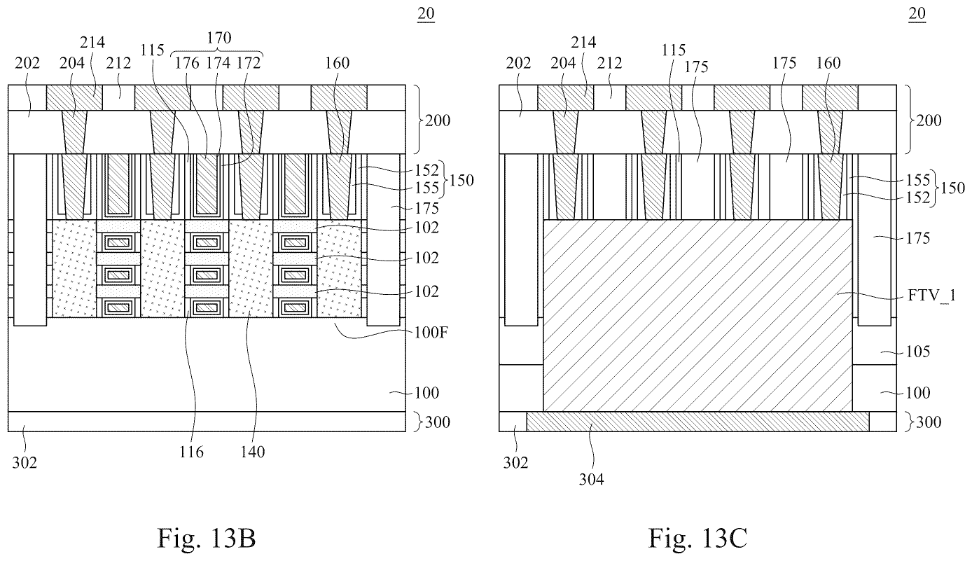

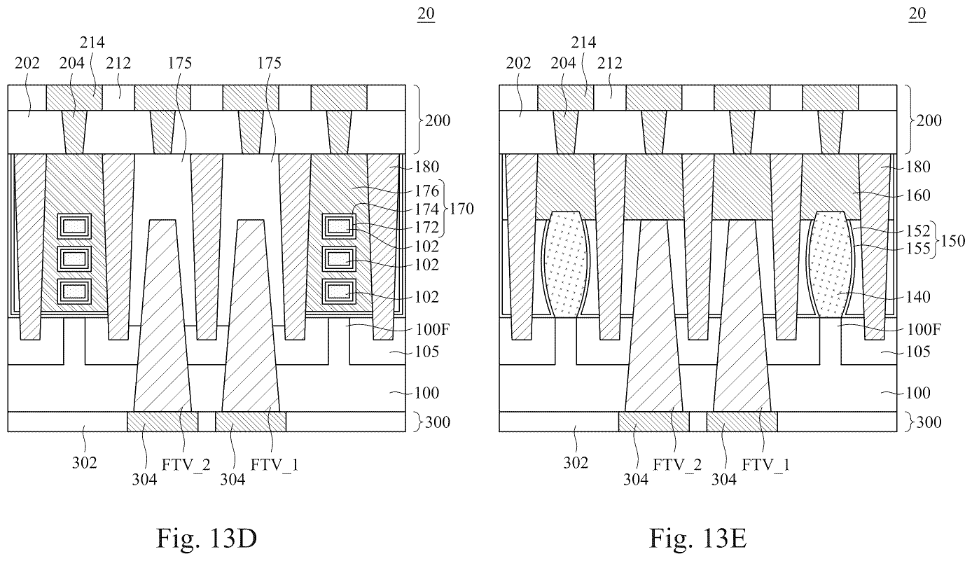

Reference is made to FIGS. 13A to 13E, in which FIG. 13A is a top view of a semiconductor device, and FIGS. 13B, 13C, 13D, and 13E are cross-sectional views along lines C1-C1, C2-C2, C3-C3, and C4-C4 of FIG. 13A, respectively. Feed-trough-vias FTV_1 and FTV_2 are formed in the recesses R1 and R2. After the feed-trough-vias FTV_1 and FTV_2 are formed, a backside interconnect structure 300 is formed over the backside of the substrate 100 and electrically connected to the feed-trough-vias FTV_1 and FTV_2. As mentioned above, because the recesses R1 and R2 may be formed with a larger window, the feed-trough-vias FTV_1 and FTV_2 may be formed with a larger volume, which will be beneficial to reduce the resistance of the feed-trough-vias FTV_1 and FTV_2.

FIG. 14 is a cross-sectional view of a semiconductor device in accordance with some embodiments of the present disclosure. Shown there is a FTV cell 30, the FTV cell 30 of FIG. 14 is similar to the FTV cell 20 of FIG. 9C, the difference between FIG. 14 and FIG. 9C is that, the feed-through-via FTV_1 may be in contact with at least three sides of each of the source/drain contacts 160. That is, bottom portion of each of the source/drain contacts 160 may be embedded in the feed-through-via FTV_1. It is noted that the feed-through-via FTV_2 may also include a similar relationship to the respective source/drain contacts 160, and thus relevant details will not be repeated for brevity.

The structure of FIG. 14 can be formed with the processes as discussed in FIGS. 10A to 13E. For example, during the process as discussed in FIGS. 12A to 12E, the etching process for forming the recess R1 (and recess R2) may include a higher etching rate to a dielectric material. Accordingly, portions of the dielectric gates 175, the dielectric structure 150, and the gate spacers 115 may be removed such that the source/drain contacts 160 are exposed through the recesses R1 and R2. Moreover, the etching process may also be tuned such that bottom portion of each of the source/drain contacts 160 may protrude into the recesses R1 and R2. Accordingly, the following formed feed-through-vias FTV_1 and FTV_2 can interface with more sides of the source/drain contacts 160, which will be beneficial for reducing the contact resistance between the feed-through-vias FTV_1 and FTV_2 and the respective source/drain contacts 160.

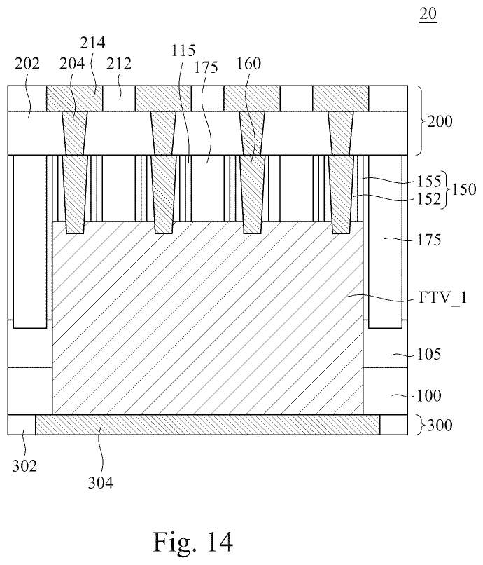

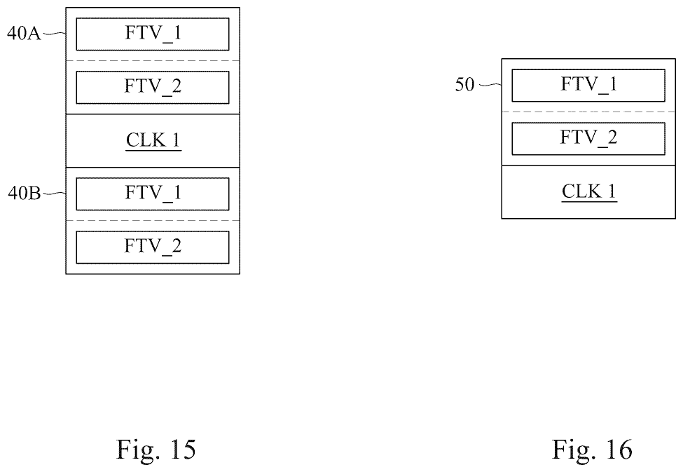

FIGS. 15 to 20 are block diagrams of semiconductor devices in accordance with some embodiments of the present disclosure. It is noted that some elements of FIGS. 15 to 20 may be similar to those described above and thus relevant details will not be repeated for brevity. In greater details, FIGS. 15 to 20 illustrate different relationship between at least one FTV cell and at least one clock cell. The FTV cell(s) as discussed in FIGS. 15 to 20 may include a same configuration as the FTV cells 10, 20, and 30 as discussed above. Specifically, the FTV cell(s) as discussed in FIGS. 15 to 20 each may include two feed-through-vias FTV_1 and FTV_2, while other elements of the FTV cell(s) are not illustrated in FIGS. 15 to 20 for brevity. The clock cell(s) as discussed in FIGS. 15 to 20 each may include an input terminal and an output terminal, in which the input terminal and the output terminal of the clock cell(s) as discussed in FIGS. 15 to 20 will be electrically connected with the corresponding FTV cell(s) as discussed in FIGS. 15 to 20. Specifically, the input terminal and the output terminal of the clock cell(s) may be electrically connected with the corresponding FTV cell(s) through the front side interconnect structure 200 and the source/drain contacts 160 as discussed above. In some embodiments, the clock cell may also be a standard cell.

Reference is made to FIG. 15. Shown there are a FTV cell 40A, a FTV cell 40B, and a clock cell CLK1 arranged between the FTV cell 40A and the FTV cell 40B. In some embodiments, an input terminal of the clock cell CLK1 can be electrically connected with both the feed-through-vias FTV_1 and FTV_2 of the FTV cell 40A, and an output terminal of the clock cell CLK1 can be electrically connected with both the feed-through-vias FTV_1 and FTV_2 of the FTV cell 40B. In the present embodiments, the two feed-through-vias in a single FTV cell and arranged in parallel may be beneficial to reduce the resistance of the FTV structure. For example, comparing with an FTV cell with single feed-through-via, the FTV cell with two feed-through-vias can reduce the resistance by more than 50%.

Reference is made to FIG. 16. Shown there are a FTV cell 50 and a clock cell CLK1 arranged adjacent to the FTV cell 50. In some embodiments, an input terminal of the clock cell CLK1 can be electrically connected with the feed-through-via FTV_1 of the FTV cell 50, and an output terminal of the clock cell CLK1 can be electrically connected with the feed-through-via FTV_2 of the FTV cell 50. In the present embodiments, the two feed-through-vias (instead of single feed-through-via) in a single FTV cell that are electrically connected with the input terminal and the output terminal of a clock cell may be beneficial for area saving. For example, two FTV cells may be needed to be electrically connected with the input terminal and the output terminal of a clock cell when each of the FTV cells includes single feed-through-via.

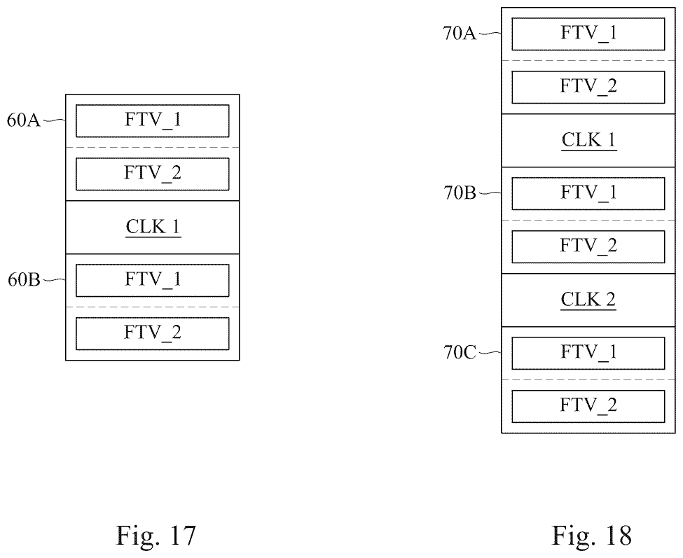

Reference is made to FIG. 17. Shown there are a FTV cell 60A, a FTV cell 60B, and a clock cell CLK1 arranged between the FTV cell 60A and the FTV cell 60B. In some embodiments, an input terminal of the clock cell CLK1 can be electrically connected with the feed-through-via FTV_1 of the FTV cell 60A. On the other hand, the output terminal of the clock cell CLK1 can be electrically connected with the feed-through-via FTV_2 of the FTV cell 60A and both the feed-through-vias FTV_1 and FTV_2 of the FTV cell 60B. In the present embodiments, the two feed-through-vias (instead of single feed-through-via) in a single FTV cell may be beneficial to adjust the input/output ratio of a clock cell.

Reference is made to FIG. 18. Shown there are a FTV cell 70A, a FTV cell 70B, a FTV cell 70C, a clock cell CLK1 arranged between the FTV cell 70A and the FTV cell 70B, and a clock cell CLK2 arranged between the FTV cell 70B and the FTV cell 70C. In some embodiments, the input terminal of the clock cell CLK1 can be electrically connected with the feed-through-vias FTV_1 and FTV2 of the FTV cell 70A. The output terminal of the clock cell CLK1 can be electrically connected with the feed-through-via FTV_1 of the FTV cell 70B. The input terminal of the clock cell CLK2 can be electrically connected with the feed-through-via FTV_2 of the FTV cell 70B. The output terminal of the clock cell CLK2 can be electrically connected with the feed-through-vias FTV_1 and FTV2 of the FTV cell 70C.

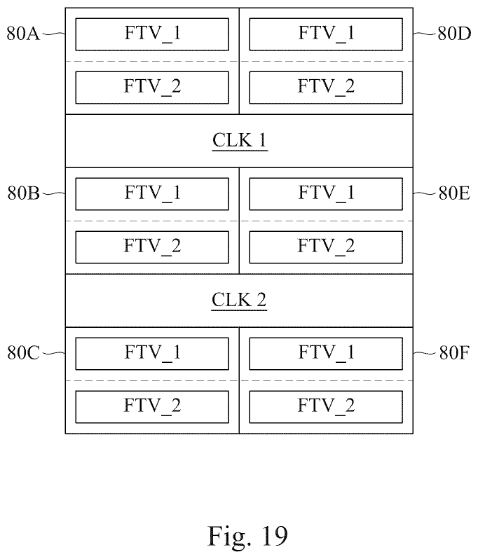

Reference is made to FIG. 19. Shown there are FTV cells 80A, 80B, 80C, 80D, 80E, and 80F, a clock cell CLK1 arranged between the FTV cells 80A/80D and the FTV cells 80B/80E, and a clock cell CLK2 arranged between the FTV cells 80B/80E and the FTV cells 80C/80F. In some embodiments, the input terminal of the clock cell CLK1 can be electrically connected with the feed-through-vias FTV_1 and FTV2 of the FTV cell 80A. The output terminal of the clock cell CLK1 can be electrically connected with the feed-through-vias FTV_1 and FTV2 of the FTV cell 80D, and can also be electrically connected with the feed-through-via FTV_1 of the FTV cell 80E. The input terminal of the clock cell CLK2 can be electrically connected with the feed-through-vias FTV_1 and FTV2 of the FTV cell 80B, and can also be electrically connected with the feed-through-via FTV_2 of the FTV cell 80E. The output terminal of the clock cell CLK2 can be electrically connected with the feed-through-vias FTV_1 and FTV2 of the FTV cell 80C, and can also be electrically connected with the feed-through-vias FTV_1 and FTV2 of the FTV cell 80F.

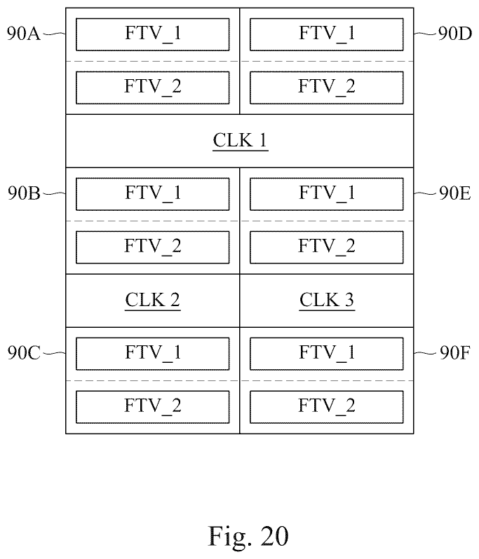

Reference is made to FIG. 20. Shown there are FTV cells 90A, 90B, 90C, 90D, 90E, and 90F, a clock cell CLK1 arranged between the FTV cells 90A/90D and the FTV cells 90B/90E, a clock cell CLK2 arranged between the FTV cell 80B and the FTV cell 80C, and clock cell CLK3 arranged between the FTV cell 80B and the FTV cell 80C. In some embodiments, the input terminal of the clock cell CLK1 can be electrically connected with the feed-through-vias FTV_1 and FTV2 of the FTV cell 80A. The output terminal of the clock cell CLK1 can be electrically connected with the feed-through-vias FTV_1 and FTV2 of the FTV cell 80D, and can also be electrically connected with the feed-through-via FTV_1 of the FTV cell 80E. The input terminal of the clock cell CLK2 can be electrically connected with the feed-through-vias FTV_1 and FTV2 of the FTV cell 80B. The output terminal of the clock cell CLK2 can be electrically connected with the feed-through-vias FTV_1 and FTV2 of the FTV cell 80C. The input terminal of the clock cell CLK3 can be electrically connected with the feed-through-via FTV2 of the FTV cell 80E. The output terminal of the clock cell CLK3 can be electrically connected with the feed-through-vias FTV_1 and FTV2 of the FTV cell 80F. The embodiments of FIGS. 18 to 20 show that the two feed-through-vias (instead of single feed-through-via) in a single FTV cell may be beneficial to provide flexible chip design.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide a FTV cell having multiple feed-through-vias. The multiple feed-through-vias may be beneficial to reduce resistance of the FTV structure, to provide area saving purpose, and to provide flexible chip design. With such configuration, the device performance can be improved.

In some embodiments of the present disclosure, a semiconductor structure includes a substrate, a gate pattern structure, source/drain contacts on opposite sides of the gate pattern structure, a first via and a second via extending through the substrate and in contact with the source/drain contacts, respectively, a gate-cut isolation structure cutting the gate pattern structure. The gate-cut isolation structure extends to a position laterally between the first via and the second via.

In some embodiments, the first via and the second via are in contact with the gate pattern structure.

In some embodiments, the first via forms a first interface with a bottom surface of the gate pattern structure and forms a second interface with a bottom surface of one of the source/drain contacts, wherein the first interface is lower than the second interface.

In some embodiments, the gate pattern structure is a metal gate structure.

In some embodiments, wherein a portion of the gate pattern structure is embedded in the first via.

In some embodiments, the first via forms a first interface with a bottom surface of the gate pattern structure and forms a second interface with a bottom surface of one of the source/drain contacts, wherein the first interface is substantially level with the second interface.

In some embodiments, bottom portions of the source/drain contacts are embedded in the first via.

In some embodiments, the gate pattern structure is made of a dielectric material.

In some embodiments of the present disclosure, a semiconductor structure includes a feed-through-via (FTV) cell and a clock cell adjacent to the FTV cell. The FTV cell includes a substrate, a gate pattern structure, source/drain contacts on opposite sides of the gate pattern structure, and a first via and a second via extending through the substrate and electrically connected with the source/drain contacts. The first via is in contact with the source/drain contacts and the gate pattern structure. The clock cell is electrically connected with one of the first via and the second via of the FTV cell.

In some embodiments, the semiconductor structure further includes a backside interconnect structure disposed on a backside of the substrate and electrically connected with the first via and the second via.

In some embodiments, the gate pattern structure comprises a gate dielectric layer and a metal layer over the gate dielectric layer, and wherein the first via is in contact with the metal layer of the gate pattern structure.

In some embodiments, the FTV cell further comprises a semiconductor channel layer in parallel with the first via and the second via, and the semiconductor channel layer is wrapped by the gate pattern structure.

In some embodiments, the semiconductor structure further includes a first isolation structure and a second isolation structure on opposite sides of the first via and in contact with the gate pattern structure.

In some embodiments, top surfaces of the first and second isolation structures are higher than a top surface of the first via.

In some embodiments, the semiconductor structure further includes gate spacers on opposite sidewalls of the gate pattern structure, wherein the first via is in contact with the gate spacers.

In some embodiments of the present disclosure, a method includes forming a semiconductor layer over a substrate; forming source/drain epitaxy structures on opposite ends of the semiconductor layer; forming a gate pattern structure over the substrate; forming source/drain contacts over the source/drain epitaxy structures, respectively, and on opposite sides of the gate pattern structure; performing a patterning process on a backside of the substrate to form a first recess and a second recess from the backside of the substrate, wherein the first recess and the second recess expose the source/drain contacts; and forming a first via and a second via in the first recess and the second recess, respectively.

In some embodiments, the first recess and the second recess further expose the gate pattern structure.

In some embodiments, forming the gate pattern structure includes forming a dummy gate structure over the substrate; and replacing the dummy gate structure with a metal gate structure.

In some embodiments, forming the gate pattern structure includes forming a dummy gate structure over the substrate; and replacing the dummy gate structure with a dielectric material.

In some embodiments, the method further includes forming an isolation structure cutting the gate pattern structure, wherein the first recess and the second recess are on opposite sides of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a gate pattern structure;
source/drain contacts on opposite sides of the gate pattern structure;
a first via and a second via extending through the substrate and in contact with the source/drain contacts, respectively; and
a gate-cut isolation structure cutting the gate pattern structure, wherein the gate-cut isolation structure extends to a position laterally between the first via and the second via.

2. The semiconductor structure of claim 1, wherein the first via and the second via are in contact with the gate pattern structure.

3. The semiconductor structure of claim 1, wherein the first via forms a first interface with a bottom surface of the gate pattern structure and forms a second interface with a bottom surface of one of the source/drain contacts, wherein the first interface is lower than the second interface.

4. The semiconductor structure of claim 3, the gate pattern structure is a metal gate structure.

5. The semiconductor structure of claim 1, wherein a portion of the gate pattern structure is embedded in the first via.

6. The semiconductor structure of claim 1, wherein the first via forms a first interface with a bottom surface of the gate pattern structure and forms a second interface with a bottom surface of one of the source/drain contacts, wherein the first interface is substantially level with the second interface.

7. The semiconductor structure of claim 1, wherein bottom portions of the source/drain contacts are embedded in the first via.

8. The semiconductor structure of claim 7, wherein the gate pattern structure is made of a dielectric material.

9. A semiconductor structure, comprising:
a feed-through-via (FTV) cell, comprising:
a substrate;
a gate pattern structure;
source/drain contacts on opposite sides of the gate pattern structure; and
a first via and a second via extending through the substrate and electrically connected with the source/drain contacts, wherein the first via is in contact with the source/drain contacts and the gate pattern structure; and
a clock cell adjacent to the FTV cell, wherein the clock cell is electrically connected with one of the first via and the second via of the FTV cell.

10. The semiconductor structure of claim 9, further comprising a backside interconnect structure disposed on a backside of the substrate and electrically connected with the first via and the second via.

11. The semiconductor structure of claim 9, wherein the gate pattern structure comprises a gate dielectric layer and a metal layer over the gate dielectric layer, and wherein the first via is in contact with the metal layer of the gate pattern structure.

12. The semiconductor structure of claim 9, wherein the FTV cell further comprises a semiconductor channel layer in parallel with the first via and the second via, and the semiconductor channel layer is wrapped by the gate pattern structure.

13. The semiconductor structure of claim 9, further comprising a first isolation structure and a second isolation structure on opposite sides of the first via and in contact with the gate pattern structure.

14. The semiconductor structure of claim 13, wherein top surfaces of the first and second isolation structures are higher than a top surface of the first via.

15. The semiconductor structure of claim 9, further comprising gate spacers on opposite sidewalls of the gate pattern structure, wherein the first via is in contact with the gate spacers.

16. A method, comprising:
forming a semiconductor layer over a substrate;
forming source/drain epitaxy structures on opposite ends of the semiconductor layer;
forming a gate pattern structure over the substrate;
forming source/drain contacts over the source/drain epitaxy structures, respectively, and on opposite sides of the gate pattern structure;
performing a patterning process on a backside of the substrate to form a first recess and a second recess from the backside of the substrate, wherein the first recess and the second recess expose the source/drain contacts; and
forming a first via and a second via in the first recess and the second recess, respectively.

17. The method of claim 16, wherein the first recess and the second recess further expose the gate pattern structure.

18. The method of claim 16, wherein forming the gate pattern structure comprises:
forming a dummy gate structure over the substrate; and
replacing the dummy gate structure with a metal gate structure.

19. The method of claim 16, wherein forming the gate pattern structure comprises:
forming a dummy gate structure over the substrate; and
replacing the dummy gate structure with a dielectric material.

20. The method of claim 16, further comprising:
forming an isolation structure cutting the gate pattern structure, wherein the first recess and the second recess are on opposite sides of the isolation structure.
